(19) United States
(12) Patent Application Publication
(10) Pub. No.: US 2024/0357884 A1
(43) Pub. Date: Oct. 24, 2024

(54) DISPLAY DEVICE

(71) Applicant: Samsung Display Co., Ltd., Yongin-si (KR)

(72) Inventors: MIN-WOO KIM, Yongin-si (KR); KYUNGHWAN MOON, Yongin-si (KR)

(21) Appl. No.: 18/415,953

(22) Filed: Jan. 18, 2024

(30) Foreign Application Priority Data
Apr. 20, 2023 (KR) 10-2023-0052050

(51) Int. Cl. H10K 59/131; G06F 3/041; G06F 3/044; H10K 59/126; H10K 59/40

(52) U.S. Cl. CPC H10K 59/131; G06F 3/0412; H10K 59/40; G06F 3/0443; G06F 3/0446; G06F 2203/04112; H10K 59/126

(57) ABSTRACT

A display device includes: a display module including a display panel and an input sensor; and a circuit board including: a first signal line electrically connected to the display panel and having a portion extending in a first extension direction; a sensing line electrically connected to the input sensing unit and having a portion extending in a second extension direction; and a shielding layer between the first signal line and the sensing line and having a first and second openings with the sensing line therebetween, wherein a portion of each of the first opening and the second opening extends in the second extension direction, wherein the sensing line crosses the first signal line between the first opening and the second opening, and wherein a distance between the first opening and the second opening is greater than or equal to a width of the sensing line.

### CROSS-REFERENCE TO RELATED APPLICATIONS

The present application claims priority to and the benefit of Korean Patent Application No. 10-2023-0052050, filed on Apr. 20, 2023, in the Korean Intellectual Property Office, the entire disclosure of which is incorporated herein by reference.

### BACKGROUND

### 1. Field

Aspects of some embodiments of the present disclosure relate to a display device.

### 2. Description of Related Art

In general, an electronic device, such as a smart phone, a digital camera, a laptop computer, a navigation, or a smart television, which displays images to users includes a display device to display the images. The display device generates an image and provides the generated image to the user through a display screen.

The display device includes a display panel to generate images and an input sensing unit located on the display panel to sense an external input. The display panel includes a plurality of pixels to generate the images, and the input sensing unit includes a plurality of sensing electrodes to sense an external input.

A circuit board is connected to the display panel and the input sensing unit. The circuit board has signal lines to transmit driving signal connected to the display panel to drive pixels and sensing lines connected to the input sensing unit to transmit the driving signals for driving the sensing electrodes or to receive a sensing signal from the sensing electrodes.

The above information disclosed in this Background section is only for enhancement of understanding of the background and therefore the information discussed in this Background section does not necessarily constitute prior art.

### SUMMARY

Embodiments of the present disclosure provide a display device capable of improving the quality of high-frequency driving signals transmitted through signal lines and reduced noise caused in sensing lines to improve reliability in input sensing.

According to some embodiments, a display device includes a display module including a display panel and an input sensing unit, and a circuit board connected to the display module. According to some embodiments, the circuit board includes a first signal line electrically connected to the display panel and having at least a portion extending in a first extension direction, a sensing line electrically connected to the input sensing unit and having at least a portion extending in a second extension direction crossing the first extension direction, and a shielding layer interposed between the first signal line and the sensing line and having a first opening and a second opening spaced apart from each other while interposing the sensing line, when viewed in a plan view. According to some embodiments, at least a portion of each of the first opening and the second opening extends in the second extension direction, the sensing line crosses the first signal line between the first opening and the second opening, when viewed in a plan view, and a distance between the first opening and the second opening is greater than or substantially equal to a width of the sensing line, when viewed in a plan view.

According to some embodiments, a portion of the first signal line may be exposed from the shielding layer through each of the first opening and the second opening, when viewed in a plan view.

According to some embodiments, the circuit board further may include a second signal line electrically connected to the display panel, spaced apart from the first signal line, and extending in parallel to the first signal line, and the second signal line crosses the sensing line, between the first opening and the second opening, when viewed in a plan view.

According to some embodiments, the circuit board may further include a grounding line interposed between the first signal line and the second signal line and extending in parallel to the first signal line, and a portion of the grounding line is exposed from the shielding layer through each of the first opening and the second opening, when viewed in a plan view.

According to some embodiments, the circuit board further may include a second signal line electrically connected to the display panel, spaced apart from the first signal line, and extending in parallel to the first signal line, the shielding layer has a third opening and a fourth opening additionally defined in the shielding layer, arranged in the second extension direction from the first opening and the second opening, respectively, and spaced apart from each other while interposing the sensing line between the third opening and the fourth opening, the second signal line crosses the sensing line between the third opening and the fourth opening, when viewed in a plan view, and a distance between the third opening and the fourth opening is greater than or substantially equal to the width of the sensing line, when viewed in a plan view.

According to some embodiments, the circuit board may further include a grounding line interposed between the first signal line and the second signal line and extending in parallel to the first signal line, and the grounding line may be interposed between the first opening and the third opening, and between the second opening and the fourth opening, when viewed in a plan view.

According to some embodiments, the sensing line may include a first part extending in the second extension direction and a second part extending in a third extension direction crossing each of the first extension direction and the second extension direction, and each of the first opening and the second opening may include a first opening region extending in the second extension direction and a second opening region extending in the third extension direction from the first opening region.

According to some embodiments, the first part may be interposed between the first opening region of the first opening and the first opening region of the second opening, and the second part may be interposed between the second opening region of the first opening and the second opening region of the second opening.

According to some embodiments, the first signal line may transmit a high-frequency signal.

According to some embodiments, a grounding voltage may be applied to the shielding layer.

According to some embodiments, the circuit board may further include a base layer under the first signal line, a first insulating layer interposed between the first signal line and the shielding layer, and a second insulating layer interposed between the shielding layer and the sensing line.

According to some embodiments, the circuit board further may include a lower insulating layer interposed between the base layer and the first signal line, and a power line interposed between the base layer and the lower insulating layer.

According to some embodiments, a display device may include a display module including a display panel and an input sensing unit, and a circuit board connected to the display module. According to some embodiments, the circuit board further may include a first signal line electrically connected to the display panel, a shielding layer on the first signal line and including a first extension region and a second extension region spaced apart from each other, and a peripheral region surrounding the first extension region and the second extension region, and a sensing line on the shielding layer, electrically connected to the input sensing unit, and including a first sensing line having a portion overlapped with the first extension region and a second sensing line having a portion overlapped with the second extension region. According to some embodiments, the first sensing line may cross the first signal line in a region overlapped with the first extension region, and the second sensing line crosses the first signal line in a region overlapped with the second extension region, when viewed in a plan view, and a width of the first extension region may be greater than or substantially same as a width of the first sensing line, in a region in which the first extension region is overlapped with the first sensing line.

According to some embodiments, the shielding layer further may include a dummy extension region spaced apart from the first extension region, extending in parallel to the first extension region, and surrounded by the peripheral region, and the dummy extension region may be in a non-overlap state with the sensing line and crosses the first signal line, when viewed in a plan view.

According to some embodiments, the shielding layer further may include a third extension region and a fourth extension region surround by the peripheral region, another portion of the first sensing line may be overlapped with the third extension region, and another portion of the second sensing line may be overlapped with the fourth extension region.

According to some embodiments, the circuit board may further includes a second signal line electrically connected to the display panel, spaced apart from the first signal line, and extending in parallel to the first signal line, and the first sensing line may cross the second signal line in a region overlapped with the third extension region, and the second sensing line crosses the second signal line in a region overlapped with the fourth extension region, when viewed in a plan view.

According to some embodiments, the first signal line may have at least a portion extending in a first extension direction in a region overlapped with the shielding layer, the first sensing line may include a first part extending in a second extension direction crossing the first extension direction and a second part extending in a third extension direction crossing each of the first extension direction and the second extension direction from the first part, and the first extension region may include a first region extending in the second extension direction and overlapped with the first part and a second region extending in the third extension direction from the first region and overlapped with the second part.

According to some embodiments, the shielding layer further may include a dummy extension region which is spaced apart from the first extension region, is in a non-overlap state with the sensing line, and is surrounded by the peripheral region, and the dummy extension region may include a first dummy region extending in the second extension direction and a second dummy region extending in the third extension direction from the first dummy region.

According to some embodiments, the circuit board may further include a grounding line spaced apart with the first signal line and extending in parallel to the first signal line.

According to some embodiments, a display device may include a display module configured to provide an image and sense an external input, and a circuit board connected to the display module. According to some embodiments, the circuit board further may include a first line electrically connected to the display module to transmit a high-frequency signal and having at least a portion extending in a first extension direction, a second line electrically connected to the display module, and having at least a portion extending in a second extension direction crossing the first extension direction, and a shielding layer interposed between the first line and the second line and having a first opening and a second opening spaced apart from each other while interposing the second line, when viewed in a plan view, wherein at least a portion of each of the first opening and the second opening extends in the second extension direction. According to some embodiments, the second line may cross the first line between the first opening and the second opening, when viewed in a plan view, and a distance between the first opening and the second opening may be greater than or substantially equal to a width of the second line, when viewed in a plan view.

### BRIEF DESCRIPTION OF THE FIGURES

The above and other characteristics and features of embodiments according to the present disclosure will become more apparent by describing in more detail aspects of some embodiments thereof with reference to the accompanying drawings.

FIG. 1 is a perspective view illustrating a display device according to some embodiments of the present disclosure.

FIG. 2 is a cross-sectional view illustrating a display device according to some embodiments of the present disclosure.

FIG. 3 is a cross-sectional view illustrating a display module according to some embodiments of the present disclosure.

FIG. 4 is a plan view illustrating some components of a display device according to some embodiments of the present disclosure.

FIG. 5 is a plan view illustrating an input sensing unit according to some embodiments of the present disclosure.

FIG. 6A is a plan view illustrating some components of a circuit board according to some embodiments of the present disclosure.

FIG. 6B is a cross-sectional view illustrating a circuit board according to some embodiments of the present disclosure.

FIGS. 6C to 6E are plan views illustrating some components of a circuit board according to some embodiments of the present disclosure.

FIGS. 7A and 7B are enlarged plan views illustrating some components of a circuit board according to some embodiments of the present disclosure.

FIGS. 8A and 8B are enlarged plan views illustrating some components of a circuit board according to some embodiments of the present disclosure.

FIGS. 9A to 9C are enlarged plan views illustrating some components according to some embodiments of the present disclosure.

FIG. 10A is an enlarged plan view illustrating some components of a circuit board according to a first comparative example.

FIG. 10B is an enlarged plan view illustrating some components of a circuit board according to a second comparative example.

### DETAILED DESCRIPTION

In the specification, the expression that a first component (or region, layer, part, portion, etc.) is “on”, “connected to”, or “coupled to” a second component means that the first component is directly on, connected to, or coupled to the second component or means that a third component is interposed therebetween.

The same reference numeral refers to the same component. In addition, in drawings, thicknesses, proportions, and dimensions of components may be exaggerated to describe the technical features effectively. The expression “and/or” includes one or more combinations which associated components are capable of defining.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, etc. are used to describe the correlation of components illustrated in drawings. The terms are relative and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

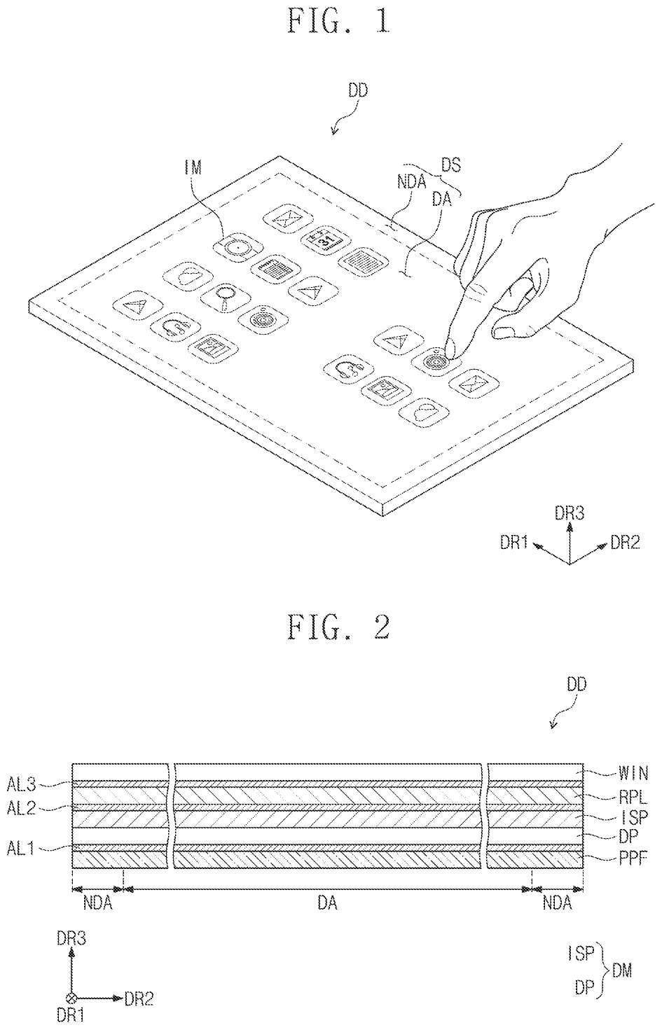

FIG. 1 is a perspective view of a display device DD according to some embodiments of the present disclosure.

The display device DD may have a shape of a rectangle having a longer side in a first direction DR1 and a shorter side in a second direction DR2 crossing the first direction DR1 (e.g., when viewed in a plan view or a view that is perpendicular or normal with respect to a display surface of the display device DD, e.g., when viewed from the third direction DR3). However, embodiments according to the present disclosure are not limited thereto, and the display device DD may have various shapes such as a circle, ellipse, or a polygon, and according to some embodiments, the display device DD may have rounded corners or apexes.

Hereinafter, a direction substantially perpendicular to a plane defined by the first direction DR1 and the second direction DR2 is defined as a third direction DR3. Furthermore, in the specification, the meaning of “when viewed from above a plane” may mean “when viewed in the third direction DR3”.

An upper surface of the display device DD may be defined as a display surface IS and may have the plane defined by the first direction DR1 and the second direction DR2. Images IM generated by the display device DD may be provided to a user through the display surface DS.

The display surface DS may include a display region DA and a non-display region NDA around (e.g., in a periphery or outside a footprint of) the display region DA. The display region DA is an area that is configured to display images and the non-display region NDA is an area at which images are not displayed. The non-display region NDA may be defined as an edge of the display device DD to surround the display region DA and printed with a specific color.

The display device DD may be used for a large electronic device such as a television, a monitor, or an outer billboard. Moreover, the display device DD may be used for small and medium electronic devices such as a personal computer, a notebook computer, a personal digital terminal, an automotive navigation system, a game console, a smartphone, a tablet, or a camera. However, the above examples are provided only for the illustrative purpose, and the display device DD may be applied to any other electronic device(s) having display capabilities without departing from the concept of the present disclosure.

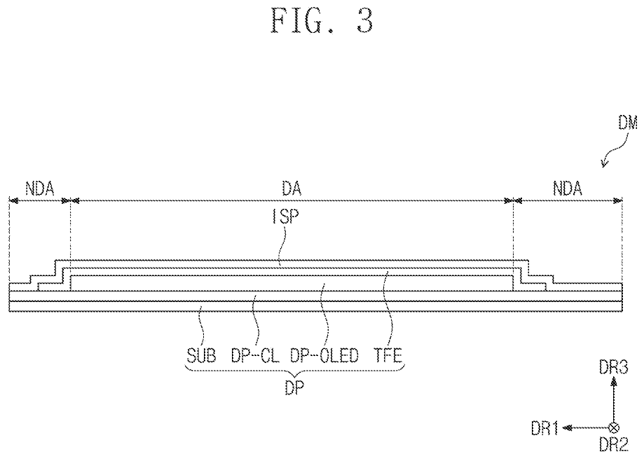

FIG. 2 is a cross-sectional view of the display device DD according to some embodiments of the present disclosure. FIG. 2 illustrates a cross-section of the display device DD when viewed in the first direction DR1.

Referring to FIG. 2, the display device DD may include a display panel DP, an input sensing unit (or input sensor or input sensing circuit or input sensing component) ISP, an anti-reflection layer RPL, a window WIN, a panel protecting film PPF, and first to third adhesive layers AL1 to AL3. The display panel DP may be a flexible display panel. For example, the display panel DP may include a plurality of electronic elements located on a flexible substrate.

The display panel DP according to some embodiments of the present disclosure may be an emissive-type display panel, and is not particularly limited thereto. For example, the display panel DP may be an organic light emitting display panel or a quantum dot light emitting display panel. The light emitting layer of the organic light emitting display layer may include an organic light emitting material. The light emitting layer of the quantum dot light emitting display panel may include a quantum dot, a quantum rod, or the like. Hereinafter, the display panel DP is an organic light emitting display panel.

The input sensing unit ISP may be located on the display panel DP. The input sensing unit ISP may include a plurality of sensors to sense an external input in a capacitive scheme. The input sensing unit ISP may be directly formed on the display panel DP when manufacturing the display device DD. However, the present disclosure is not limited thereto. The input sensing unit ISP is manufactured separately from the display panel DP, and may be attached to the display panel DP by the adhesive layer

The anti-reflection layer RPL may be located on the input sensing unit ISP. The anti-reflection layer RPL may reduce the reflectance of external light incident from the top surface of the display device DD toward the display panel DP. The anti-reflection layer RPL may include a retarder and a polarizer.

The window WIN may be located on the anti-reflection layer RPL. The window WIN may protect the display panel DP, the input sensing unit ISP, and the anti-reflection layer RPL from external scratches and impacts.

The panel protecting film PPF may be located under the display panel DP. The panel protecting film PPF may protect a bottom surface of the display panel DP. The panel protecting film PPF may include a flexible plastic material such as Polyethyleneterephthalate (PET).

The first adhesive layer AL1 may be interposed between the display panel DP and the panel protecting film PPF to combine the display panel DP with the panel protecting film PPF. The second adhesive layer AL2 may be interposed between the anti-reflection layer RPL and the input sensing unit ISP to combine the anti-reflection layer RPL and the input sensing unit ISP. The third adhesive layer AL3 may be interposed between the window WIN and the anti-reflection layer RPL to combine the window WIN with the anti-reflection layer RPL.

FIG. 3 is a cross-sectional view of a display module DM according to some embodiments of the present disclosure. For example, FIG. 3 illustrates a cross-section of the display module DM when viewed in the first direction DR1.

Referring to FIG. 3, the display module DM may include the display panel DP and the input sensing unit ISP.

The display panel DP may include a substrate SUB, a circuit element layer DP-CL located on the substrate SUB, a display element layer DP-OLED located on the circuit element layer DP-CL, and an encapsulation layer TFE located on the display element layer DP-OLED.

The substrate SUB may include the display region DA and the non-display region NDA around the display region DA. The display element layer DP-OLED is located in the display region DA. The substrate SUB may include a flexible plastic material such as polyimide (PI).

A plurality of pixels may be located in the circuit element layer DP-CL and the display element layer DP-OLED. Each of the pixels may include a transistor located in the circuit element layer DP-CL and a light emitting element located in the display element layer DP-OLED and connected to the transistor.

The thin film encapsulation layer TFE may cover the display element layer DP-OLED. The thin film encapsulation layer TFE may include an inorganic layer, an organic layer, and an inorganic layer sequentially stacked. The inorganic layers include inorganic materials and may protect pixels from moisture/oxygen. The organic layer includes an organic material and may protect pixels from foreign substances such as dust particles.

The input sensing unit ISP acquires coordinate information of an external input. The input sensing unit ISP may have a multi-layer structure. The input sensing unit ISP may include a single layer or a multi-layer conductive layer. The input sensing unit ISP may include a single-layer or multi-layer insulating layer. The input sensing unit ISP may detect an external input, for example, through a capacitive manner. According to embodiments of the present disclosure, an operation method of the input sensing unit ISP is not particularly limited, and the input sensing unit ISP may sense the external input through an electromagnetic induction method or a pressure sensing method according to some embodiments of the present disclosure.

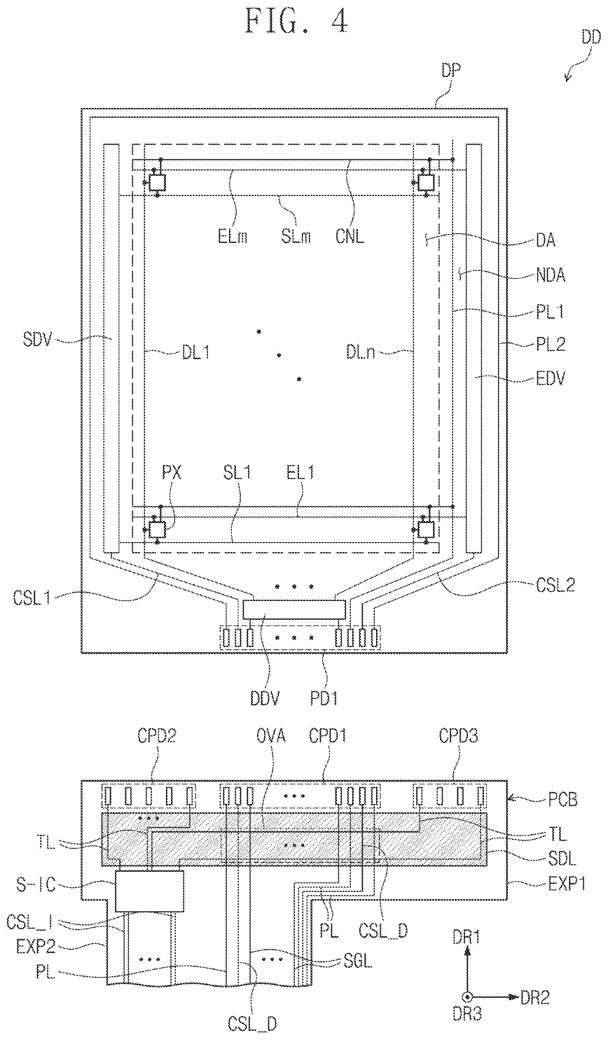

FIG. 4 is a plan view of some components of the display device DD according to some embodiments of the present disclosure.

Referring to FIG. 4, the display device DD may include the display panel DP, a scan driver SDV, a data driver DDV, an emission driver EDV, a plurality of first pads PD1, a circuit board PCB, a sensing controller S-IC, a plurality of first connection pads CPD1, a plurality of second connection pads CPD2, and a plurality of third connection pads CPD3.

The display panel DP may have a rectangular shape having longer sides extending in the first direction DR1 and shorter sides extending in the second direction DR2, but the shape of the display panel DP is not limited thereto. The display panel DP may include the display region DA and the non-display region NDA surrounding the display region DA.

The display panel DP may include multiple pixels PX, multiple scanning lines SL1 to SLm, multiple data lines DL1 to DLn, multiple light emitting lines EL1 to ELm, first and second control lines CSL1 and CSL2, first and second power lines PL1 and PL2, and power connection lines CNL. In this case, ‘m’ and ‘n’ are natural numbers.

The pixels PX may be located in the display region DA. The scan driver SDV and the emission driver EDV may be located in the non-display region NDA adjacent to longer sides of the display panel DP, respectively. The data driver DDV may be located in the non-display region NDA adjacent to any one of the shorter sides of the display panel DP. When viewed in a plan view, the data driver DDV may be adjacent to a lower end of the display panel DP. The data driver DDV may be manufactured in the form of an integrated circuit chip and mounted on the display panel DP.

The scanning lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The light emitting lines EL1 to ELm may extend in the second direction DR2 and may be connected to the pixels PX and the emission driver EDV.

The first power line PL1 may extend in the first direction DR1 and may be located in the non-display region NDA. The first power line PL1 may be interposed between the display region DA and the emission driver EDV, but is not limited thereto, and the first power line PL1 may be interposed between the display region DA and the scan driver SDV.

The power connection lines CNL may extend in the second direction DR2 and may be arranged in the first direction DR1. The power connection lines CNL may be connected to the first power line PL1 and the pixels PX. The first voltage may be applied to the pixels PX through the first power line PL1 and the power connection lines CNL connected to each other.

The second power line PL2 may be located in the non-display region NDA. The second power line PL2 may extend along the longer sides of the display panel DP and another shorter side of the display panel DP in which the data driver DDV is not located. The second power line PL2 may be located outside the scan driver SDV and the emission driver EDV.

According to some embodiments, the second power line PL2 may extend toward the display region DA and may be connected to the pixels PX. A second voltage having a level lower than the first voltage may be applied to the pixels PX through the second power line PL2.

The first control line CSL1 may be connected to the scan driver SDV and may extend toward a lower end of the display panel DP when viewed in a plan view. The second control line CSL2 may be connected to the emission driver EDV and may extend toward a lower end of the display panel DP when viewed in a plan view. The data driver DDV may be interposed between the first control line CSL1 and the second control line CSL2.

The first pads PD1 may be located on the display panel DP. The first pads PD1 may be closer to the lower end of the display panel DP than the data driver DDV.

The data driver DDV, the first power line PL1, the second power line PL2, the first control line CSL1, and the second control line CSL2 may be connected to the first pads PD1. The data lines DL1 to DLn may be connected to the data driver DDV, and the data driver DDV may be connected to the first pads PD1 corresponding to the data lines DL1 to DLn.

The circuit board PCB may be implemented in the form of a flexible circuit board, but the present disclosure is not limited thereto. The circuit board PCB may be implemented in a rigid type. The sensing controller S-IC may be manufactured in the form of an integrated circuit chip and mounted on the circuit board PCB.

The first connection pads CPD1, the second connection pads CPD2, and the third connection pads CPD3 may be located on the circuit board PCB. When viewed in a plan view, the first connection pads CPD1, the second connection pads CPD2, and the third connection pads CPD3 may be adjacent to an upper portion of the circuit board PCB. The upper portion of the circuit board PCB may face a lower portion of the display panel DP.

The first connection pads CPD1 may be interposed between the second connection pads CPD2 and the third connection pads CPD3. For example, the second connection pads CPD2 may be located on the left side of the first connection pads CPD1, and the third connection pads CPD3 may be located on the right side of the first connection pads CPD1.

The circuit board PCB may be connected to the display module DM (see FIG. 2). The circuit board PCB may be connected to the display panel DP. As the first connection pads CPD1 are connected to the first pads PD1, the circuit board PCB may be electrically connected to the display panel DP.

The circuit board PCB may include a first extension unit EXP1 extending in the second direction DR2 and a second extension unit EXP2 extending in the first direction DR1 from a specific portion of the first extension unit EXP1. The second extension unit EXP2 may extend in a direction away from the display panel DP. According to some embodiments, the second extension unit EXP2 may be connected to a system board located outside. The system board may control the overall operation of the display device DD.

The sensing controller S-IC may be located on the first extension unit EXP1. The sensing controller S-IC may be adjacent to the second extension unit EXP2. The first connection pads CPD1, the second connection pads CPD2, and the third connection pads CPD3 may be located on the first extension unit EXP1 and may be adjacent to the upper portion of the first extension unit EXP1 when viewed in a plan view.

A plurality of power lines PL, a plurality of control lines CSL_D, a plurality of signal lines SGL (or first lines), a plurality of sensing lines TL (second lines), and a plurality of sensing signal lines CSL_I may be located inside the circuit board (PCB).

The signal lines SGL, the power lines PL, and the control lines CSL_D may be located in the second extension unit EXP2 and may extend in the first direction DR1. The signal lines SGL, the power lines PL, and the control lines CSL_D may be connected to the system board through the second extension unit EXP2.

The signal lines SGL, the power lines PL, and the control lines CSL_D may be located in the first extension unit EXP1 while extending in the first direction DR1, the second direction DR2, and the first direction DR1, respectively, and connected to the first connection pads CPD1, respectively. The signal lines SGL, the power lines PL, and the control lines CSL_D may be connected to the first pads PD1 through the first connection pads CPD1, thereby being connected to the display panel DP.

The sensing signal lines CSL_I may be located in the second extension unit EXP2 and may extend in the first direction DR1 to be connected to the sensing controller S-IC in the first extension unit EXP1.

The sensing lines TL may be located in the first extension unit EXP1 and may extend in the first direction DR1, the second direction DR2, and the first direction DR1, respectively, to be connected to the second connection pads CPD2 or the third connection pads CPD3. Left sensing lines of the sensing lines TL may be connected to the second connection pads CPD2, and right sensing lines of the sensing lines TL may be connected to the third connection pads CPD3, respectively. The sensing lines TL may be connected to the input sensing unit ISP (see FIG. 2) through the second connection pads CPD2 or the third connection pads CPD3. According to some embodiments, the sensing lines TL connected to the second connection pads CPD2 may be transmission lines that transmit driving signals for driving the sensing electrodes, and the sensing lines TL connected to the third connection pads CPD3 may be reception lines that receive sensing signals from the sensing electrodes, but the present disclosure is not limited to thereto.

According to some embodiments, the sensing lines TL connected to the third connection pads CPD3 may be overlapped with the signal lines SGL. More specifically, the sensing lines TL connected to the third connection pads CPD3 may cross the signal lines SGL when viewed on the plane, as the sensing lines TL connected to the third connection pads CPD3 extend from the sensing controller S-IC, which is located at the left side of the first extension unit EXP1, to the third connection pads CPD3 located at the right side of the first extension unit EXP1. A region formed as the sensing lines TL cross the signal lines SGL on the circuit board PCB when viewed in a plan view may be defined as an overlap region OVA. Meanwhile, the sensing lines TL connected to the second connection pads CPD2 may not be overlapped with the signal lines SGL.

According to some embodiments, a shielding layer SDL is arranged to be overlapped with at least some of the sensing lines TL, on the circuit board PCB. The shielding layer SDL may be located between the sensing lines TL and the signal lines SGL in the overlap region OVA. A ground (or ground) voltage may be applied to the shielding layer SDL. Accordingly, the shielding layer SDL may reduce coupling phenomenon between the sensing lines TL and the signal lines SGL which are adjacent to each other or crossing each other when viewed in a plan view.

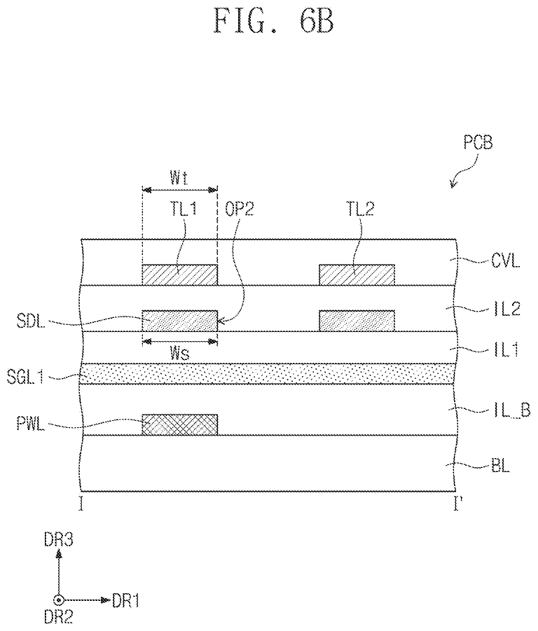

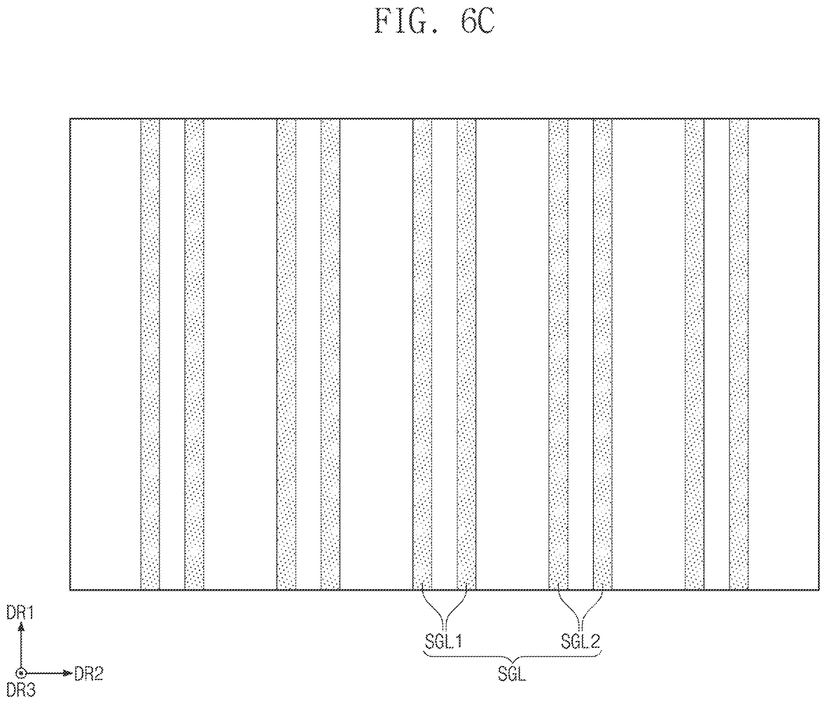

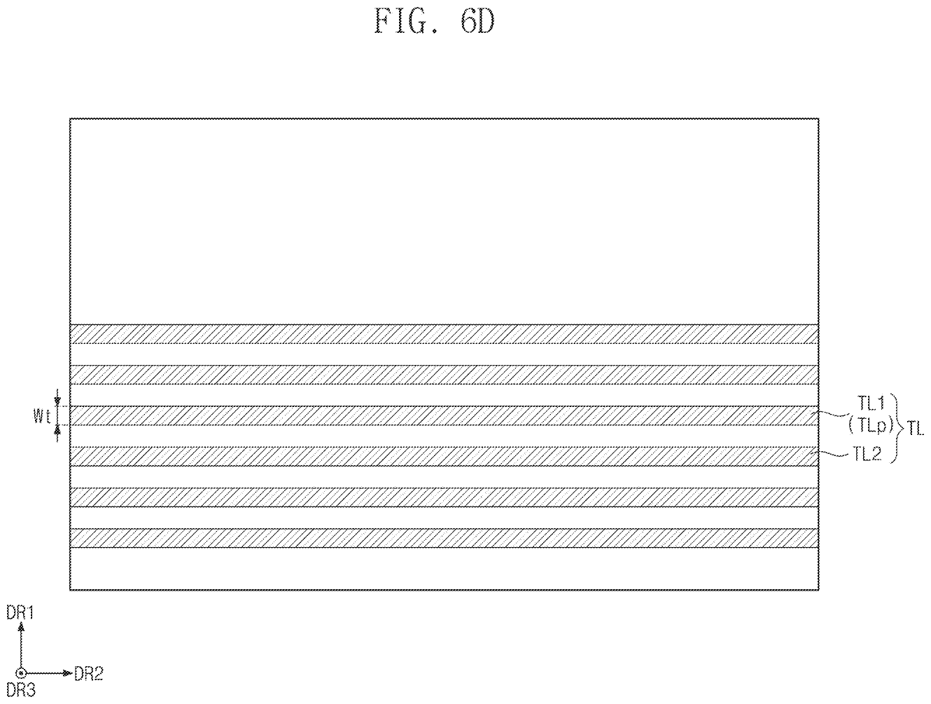

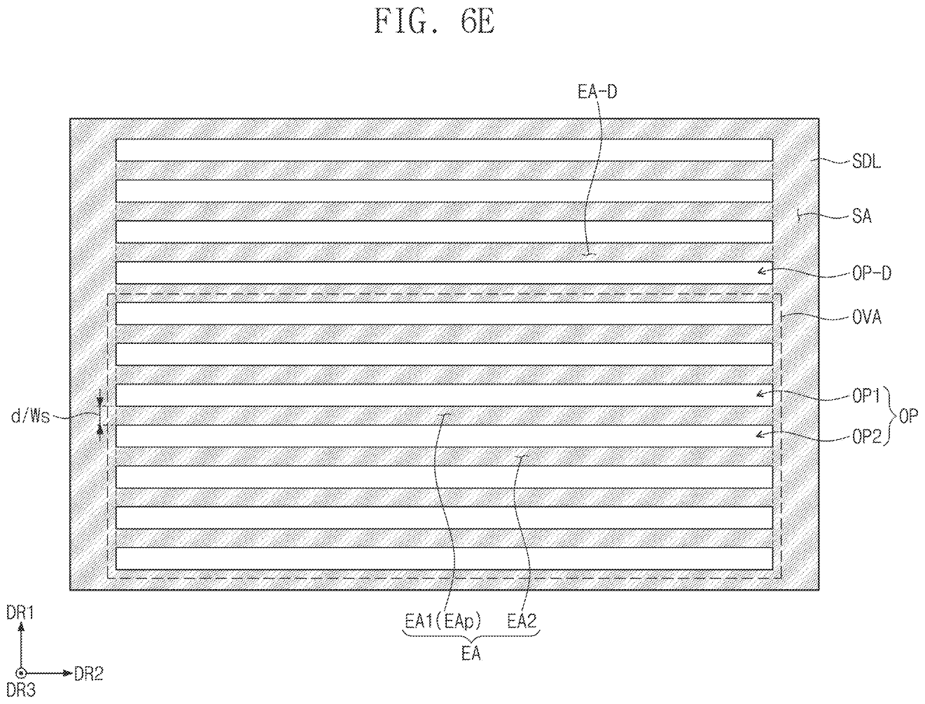

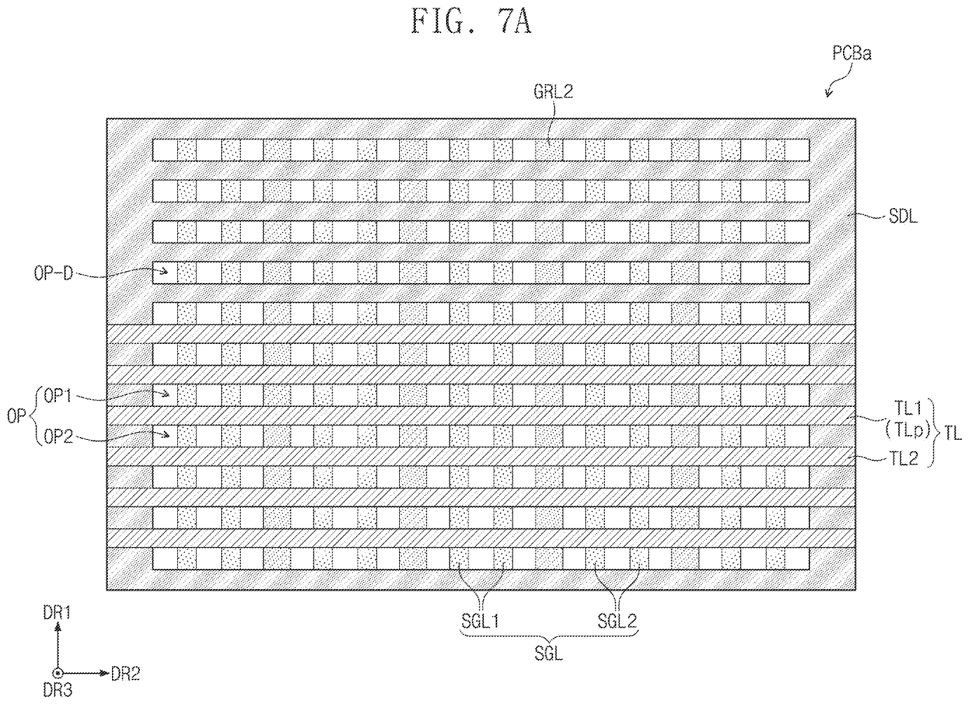

Meanwhile, the shape of the shielding layer SDL is exemplary, and the shielding layer SDL may be arranged to be overlapped with only some sensing lines TL outside the overlap region OVA, or a plurality of shielding layers SDL may be arranged to be spaced apart from each other to be overlapped with mutually different sensing lines TL. The configuration of the sensing lines TL and the signal lines SGL crossing each other and the shielding layer SDL interposed between the sensing lines TL and the signal lines SGL will be described in detail with reference to FIG. 6A, which is an expanded view of the overlap region OVA.

According to some embodiments, each of the sensing lines TL (e.g., reception lines) connected to the third connection pads CPD3 may cross all of the signal lines SGL. However, the present disclosure is not limited thereto. The sensing lines TL connected to the third connection pads CPD3 may cross some of signal lines SGL, and some of the sensing lines TL connected to the third connection pads CPD3 may cross the signal lines SGL.

The system board may include a timing controller for controlling an operation of the display panel DP. According to some embodiments, the second extension unit EXP2 may be connected to a voltage generator located outside. The timing controller may output scan control signals, image signals, and emission control signals. The voltage generator may generate a first voltage and a second voltage.

The scan control signal and the emission control signal may be provided to the first control line CSL1 and the second control line CSL2 through the control lines CSL_D, respectively. The scan control signal may be provided to the scan driver SDV through the first control line CSL1. The emission control signal may be provided to the emission driver EDV through the second control line CSL2. The image signals may be provided to the data driver DDV through the signal lines SGL.

The scan driver SDV generates a plurality of scan signals in response to the scan control signal, and the scan signals may be applied to the pixels PX through the scanning lines SL1 to SLm. The emission driver EDV generates a plurality of light emitting signals in response to the light emitting control signal, and the light emitting signals may be applied to the pixels PX through the light emitting lines EL1 to ELm.

The data driver DDV may generate a plurality of data voltages corresponding to the image signals. The data voltages may be applied to the pixels PX through the data lines DL1 to DLn. The first voltage and the second voltage may be provided to the first power line PL1 and the second power line PL2 through the power lines PL.

The pixels PX may receive data voltages in response to scan signals. The pixels PX may display an image by emitting light having brightness corresponding to the data voltages in response to the light emitting signals. The light emission time of the pixels PX may be controlled by light emitting signals.

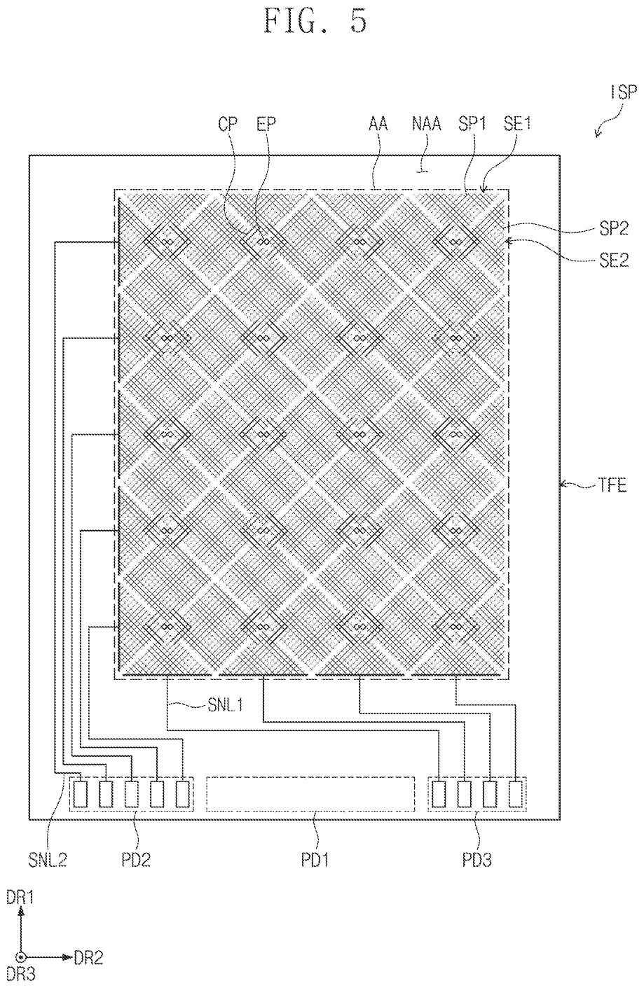

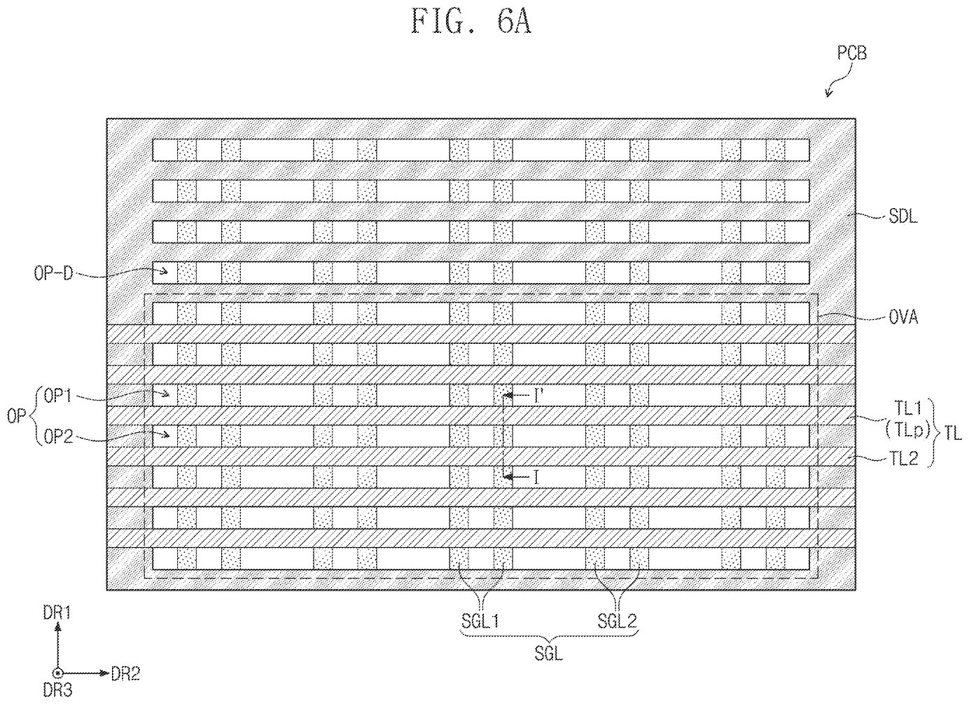

The sensing controller S-IC may be connected to sensing electrodes of the input sensing unit ISP (see FIG. 5) to be described below through the second connection pads CPD2 and the third connection pads CPD3.

FIG. 5 is a plan view of the input sensing unit ISP according to some embodiments of the present disclosure.

Referring to FIGS. 4 and 5, the input sensing unit ISP may include a plurality of sensing electrodes SE1 and SE2, a plurality of sensing lines SNL1 and SNL2, a plurality of second pads PD2, and a plurality of third pads PD3. The sensing electrodes SE1 and SE2, the sensing lines SNL1 and SNL2, the second pads PD2, and the third pads PD3 may be located on the thin film encapsulation layer TFE.

The plane region of the input sensing unit ISP may include an active region AA and an inactive region NAA around the active region AA. The active region AA may be overlapped with the display region DA, and the inactive region NAA may be overlapped with the non-display region NDA. The sensing electrodes SE1 and SE2 may be located in the active region AA, and the second pads PD2 and the third pads PD3 may be located in the inactive region NAA.

The sensing lines SNL1 and SNL2 may be connected to one end of the sensing electrodes SE1 and SE2, and may extend to the inactive region NAA to be connected to the second pads PD2 and the third pads PD3. The input sensing unit ISP may be connected to the circuit board PCB. According to some embodiments, the second pads PD2 may be connected to the second connection pads CPD2 located on the circuit board PCB, and the third pads PD3 may be connected to the third connection pads CPD3 located on the circuit board PCB. Some of the sensing lines TL located on the circuit board PCB may be connected to the input sensing unit ISP through the second connection pads CPD2, and the remaining lines of the sensing lines TL located on the circuit board PCB may be connected to the input sensing unit ISP through the third connection pads CPD3.

The sensing electrodes SE1 and SE2 may include the plurality of first sensing electrodes SE1 extending in the first direction DR1 and arranged in the second direction DR2 and the plurality of second sensing electrodes SE2 extending in the second direction DR2 and arranged in the first direction DR1. The second sensing electrodes SE2 may extend to be insulated from the first sensing electrodes SE1 while crossing the first sensing electrodes SE1.

The sensing lines SNL1 and SNL2 may include the plurality of first sensing lines SNL1 connected to the first sensing electrodes SE1 and the plurality of second sensing lines SNL2 connected to the second sensing electrodes SE2. The first sensing lines SNL1 may be connected to the third pads PD3. The second sensing lines SNL2 may be connected to the second pads PD2. Accordingly, the transmission lines of the sensing lines TL placed on the circuit board PCB are connected to the second sensing lines SNL2 placed in the input sensing unit ISP. The reception lines of the sensing lines TL placed on the circuit board PCB may be connected to the first sensing lines SNL1 placed on the input sensing unit ISP.

The first sensing electrodes SE1 may be defined as output sensing electrodes, and the second sensing electrodes SE2 may be defined as input sensing electrodes. The input sensing unit ISP may be driven in a mutual sensing mode. For example, the sensing controller S-IC may provide driving signals to the input sensing unit ISP and receive sensing signals from the input sensing unit ISP.

The driving signals may be applied to the second sensing electrodes SE2 through transmission lines (e.g., sensing lines connected to the second connection pads CPD2) of the sensing lines TL and the second sensing lines SNL2. The sensing signals sensed by the first sensing electrodes SE1 may be output through the first sensing lines SNL1 and may be provided to the sensing controller S-IC through the reception lines (for example, the sensing lines TL connected to the third connection pads CPD3) of the sensing lines TL.

The sensing controller S-IC may receive control signals for generating the driving signals, through the plurality of sensing signal lines CSL_I. In addition, the sensing controller S-IC may process the sensing signals and output the sensing signals through the plurality of sensing signal lines CSL_I.

Each of the first sensing electrodes SE1 may include a plurality of first sensing units SP1 arranged in the first direction DR1 and a plurality of connection patterns CP connecting the first sensing units SP1. Each of the connection patterns CP may be interposed between two first sensing units SP1 adjacent to each other in the first direction DR1 to connect the two first sensing units SP1 to each other.

Each of the second sensing electrodes SE2 may include the plurality of second sensing units SP2 arranged in the second direction DR2 and the plurality of extension patterns EP extending from the second sensing units SP2. Each of the extension patterns EP may be located between two second sensing units SP2 adjacent to each other in the second direction DR2 and may extend from the two second sensing units SP2.

The first sensing units SP1 and the second sensing units SP2 may have a mesh shape. The first sensing units SP1 and the second sensing units SP2 may be spaced apart from each other being overlapped each other, and may be alternately arranged. The capacitance may be formed by the first sensing units SP1 and the second sensing units SP2. The extension patterns EP may not be overlapped with the connection patterns CP.

The first and second sensing units SP1 and SP2 and the extension patterns EP may be located at the same layer. The connection patterns CP may be located at a layer different from that of the first and second sensing units SP1 and SP2 and the extension patterns EP.

FIG. 6A is a plan view illustrating some components of the circuit board PCB according to some embodiments of the present disclosure. FIG. 6B is a cross-sectional view of the circuit board PCB according to some embodiments cut along the line I-I′ of FIG. 6A. FIGS. 6C to 6E are plan views illustrating some components of a circuit board PCB (see FIG. 6A) according to some embodiments of the present disclosure.

FIGS. 6A and 6C to 6E are enlarged views illustrating the overlap region OVA illustrated in FIG. 4 and a region adjacent to the overlap region OVA. FIG. 6A illustrates the signal lines SGL, the sensing lines TL, and the shielding layer SDL on the circuit board PCB. For convenience of explanation, FIG. 6C illustrates only the signal lines SGL of FIG. 6A, FIG. 6D illustrates only the sensing lines TL of FIG. 6A, and FIG. 6E illustrates only the shielding layer SDL of FIG. 6A.

Referring to FIGS. 6A to 6C, in the overlap region OVA, each of the signal lines SGL may extend in the first extension direction and may be arranged in a direction perpendicular to the first extension direction. According to some embodiments, the first extension direction may be a direction parallel to the first direction DR1. In other words, in the overlap region OVA, the signal lines SGL may extend in the first direction DR1 and may be arranged in the second direction DR2.

The following description will be made in that the first extension direction is a direction parallel to the first direction DR1.

According to some embodiments, the signal lines SGL may be arranged while every two signal lines form one pair. The signal lines SGL may be arranged in such a manner that two signal lines are arranged adjacent to each other, and the distance between two signal lines forming one pair may be narrower than the distance between two pairs of signal lines adjacent to each other while forming mutually different pairs. However, the present disclosure is not limited thereto, and all signal lines SGL may be arranged at uniform distances. Even in this case, the signal lines SGL are regarded as being arranged while every two signal lines adjacent to each other form one pair, and the distance between two signal lines forming one pair is regarded as being equal to the distance between two pairs of signal lines adjacent to each other while forming mutually different pairs.

In the present specification, each of two signal lines forming any one pair of signal lines SGL may be defined as first signal lines SGL1, and two signal lines forming another pair adjacent to the one pair may be defined as second signal lines SGL2. For example, the first signal lines SGL1 may correspond to an i-th pair of signal lines (that is, (2i−1)-th and 2i-th signal lines) of the signal lines SGL, and the second signal lines SGL2 may correspond to an (i+1)-th pair of signal lines (that is, (2i+1)-th and (2i+2)-th signal lines). In this case, ‘i’ is a natural number.

FIGS. 6A and 6C illustrate that ten signal lines SGL are located in the overlap region OVA, and cross the sensing lines TL, when viewed in a plan. However, FIGS. 6A and 6C illustrate the number of signal lines SGL located in the overlap region OVA, but embodiments according to the present disclosure is not limited to any embodiment.

As illustrated in FIG. 6B, the circuit board PCB according to some embodiments may include a base layer BL, a lower insulating layer IL_B located on the base layer BL, first and second insulating layers IL1 and IL2 sequentially stacked on the lower insulating layer IL_B, and a cover layer CVL located on the second insulating layer IL2.

Each of the base layer BL, the lower insulating layer IL_B, the first and second insulating layers IL1 and IL2, and the cover layer CVL may include an insulating material. Each of the base layer BL, the lower insulating layer IL_B, the first and second insulating layers IL1 and IL2, and the cover layer CVL may include an organic insulating material, and the organic insulating material may include a polymer material such as polyimide (PI), polyethylene terephthalate (PET), and polyethylene terephthalate. For example, each of the base layer BL, the lower insulating layer IL_B, the first and second insulating layers IL1 and IL2, and the cover layer CVL may include polyimide (PI).

According to some embodiments, the signal lines SGL may be located on the lower insulating layer IL_B and covered by the first insulating layer IL1.

Referring to FIGS. 6A, 6B, and 6D, in the overlap region OVA, the sensing lines TL may respectively extend in a second extension direction and may be arranged in a direction perpendicular to the second extension direction. The second extension direction may be a direction crossing the first extension direction in which the signal lines SGL extend. According to some embodiments, the second extension direction may be a direction perpendicular to the first extension direction and parallel to the second direction DR2. In other words, in the overlap region OVA, each of the sensing lines TL may extend in the second direction DR2 and may be arranged in the first direction DR1. However, the present disclosure is not limited thereto, and the second extension direction is not perpendicular to the first extension direction and may be a direction crossing the first extension direction.

In the present specification, two sensing lines TL, which are located adjacent to each other, of the sensing lines TL may be defined as a first sensing line TL1 and a second sensing line TL2, respectively. For example, the first sensing line TL1 may correspond to a j-th sensing line of the sensing lines TL, and the second sensing line TL2 may correspond to a (j+1)-th sensing line of the sensing lines TL. In this case, ‘j’ is a natural number.

According to some embodiments, the sensing lines TL may be arranged at uniform distances. In other words, all sensing lines TL have an equal distance between adjacent sensing lines. However, the present disclosure is not limited thereto, and the sensing lines TL may be arranged at different distances depending on positions. Alternatively, a plurality of sensing lines form a group, and the sensing lines may be arranged at uniform distances within one group, and groups may be arranged at wider distances.

FIGS. 6A and 6D illustrate that six sensing lines TL are placed in the overlap region OVA and cross the signal lines SGL. However, FIGS. 6A and 6D illustrate the number of sensing lines TL located in the overlap region OVA, and embodiments according to the present disclosure are not limited to any embodiment.

According to some embodiments, the sensing lines TL may be located on the signal lines SGL. The sensing lines TL may be located on the second insulating layer IL2 to be covered by the cover layer CVL.

Referring to FIGS. 6A, 6B, and 6E, openings OP having a specific pattern may be defined in the overlap region OVA of the shielding layer SDL. Each of the openings OP defined in the shielding layer SDL may extend in the second extension direction and may be arranged in a direction perpendicular to the second extension direction. According to some embodiments, each of the openings OP may extend in the second direction DR2 and may be arranged in the first direction DR1.

In this specification, two of the openings OP located adjacent to each other may be defined as a first opening OP1 and a second opening OP2, respectively. For example, the first opening OP1 may correspond to a k-th opening of the openings OP, and the second opening OP2 may correspond to the (k+1)-th opening of the openings OP. In this case, ‘k’ is a natural number.

As the openings OP having the specific pattern are defined in the shielding layer SDL, the shielding layer SDL may include extension regions EA arranged to be spaced apart from each other and peripheral regions SA surrounding the extension regions EA. The extension region EA may be defined as a region between adjacent openings OP. In correspondence to the extension direction and the arrangement direction of the openings OP, the extension regions EA may also be arranged in a direction perpendicular to the second extension direction while extending in the second extension direction. According to some embodiments, each of the extension regions EA may extend in the second direction DR2 and may be arranged in the first direction DR1. The following description will be made in that the second extension direction is a direction parallel to the second direction DR2.

The openings OP may have a rectangular shape having longer sides extending in the second direction DR2, when viewed in a plan view. Accordingly, each of the extension regions EA may also have a rectangular shape having longer sides extending in the second direction DR2 when viewed in a plan view.

According to some embodiments of the present disclosure, dummy openings OP-D having a specific pattern may be further defined in the shielding layer SDL outside the overlap region OVA. According to some embodiments, the dummy openings OP-D may be defined to have a pattern similar to that of the openings OP.

More specifically, the dummy openings OP-D may be spaced apart from the openings OP in the first direction DR1, and the dummy openings OP-D may extend in the second direction DR2 and may be arranged in the first direction DR1.

When the dummy openings OP-D having a specific pattern are further defined in the shielding layer SDL, the shielding layer SDL may further include dummy extension regions EA-D arranged to be spaced apart from each other and surrounded by the peripheral region SA. The dummy extension region EA-D may be defined as a region between adjacent dummy openings OP-D or a region between adjacent dummy openings OP-D and openings OP.

The shielding layer SDL according to some embodiments may be located between the signal lines SGL and the sensing lines TL. The shielding layer SDL may be located on the first insulating layer IL1 and covered by the second insulating layer IL2.

Referring to FIGS. 6A to 6E, the sensing lines TL located in the overlap region OVA when viewed in a plan view may be located in every space between adjacent openings OP. Hereinafter, a pair of first and second openings OP1 and OP2 of the openings OP, one extension region (hereinafter, referred to as an extension region EAp) defined by the pair of first and second openings OP1 and OP2, and one sensing line (hereinafter, referred to as a “sensing line TLp”) located between the pair of first and second openings OP1 and OP2 will be representatively described, which is applied all sensing lines TL located in the overlap region OVA in common.

A portion of the sensing line TLp may be interposed between the first and second openings OP1 and OP2, when viewed in a plan view, and the sensing line TLp may not be overlapped with the first and second openings OP1 and OP2, respectively. A portion of the sensing line TLp may be overlapped with the extension region EAp defined by the first and second openings OP1 and OP2 of the shielding layer SDL, when viewed in a plan view.

According to some embodiments, a distance ‘d’ between the first and second openings OP1 and OP2 when viewed in a plan view may be greater than or substantially equal to a width ‘Wt’ in the first direction DR1 of the sensing line TLp. The separation distance ‘d’ between the first and second openings OP1 and OP2 is the same as a width ‘Ws’ in the first direction DR1 of the extension region EAp.

Accordingly, the width ‘Ws’ in the first direction DR1 of the extension region EAp may also be greater than or substantially equal to the width ‘Wt’ in the first direction DR1 of the sensing line TL. In the specification, the meaning of “substantially equal” may include a case in which a difference is made due to a process error in the process of forming the sensing lines TL and/or forming the openings OP in the shielding layer SDL.

FIG. 6A illustrates that the distance ‘d’ between the first and second openings OP1 and OP2, that is, the width Ws of the extension region EAp, is equal to the width ‘Wt’ of the sensing line TLP.

When viewed in a plan view, the sensing line TLp may cross the signal lines SGL between the first and second openings OP1 and OP2. In other words, when viewed in a plan view, the sensing line TLp may cross the signal lines SGL in a region overlapped with the extension region EA.

According to some embodiments, each of the first and second openings OP1 and OP2 may cross all signal lines SGL located in the overlap region OVA when viewed in a plan view. Specifically, each of the first and second openings OP1 and OP2 may continuously extend to cross all signal lines SGL located in the overlap region OVA, when viewed in a plan view. Accordingly, each of the signal lines SGL is partially exposed from the shielding layer SDL by the first opening OP1, and another portion may be exposed from the shielding layer SDL by the second opening OP2.

In this specification, an extension region, which is overlapped with the first sensing line TL1, of the extension regions EA may be defined as a first extension region EA1, and an extension region, which is overlapped with the second sensing line TL2, of the extension regions EA may be defined as a second extension region EA2.

For example, the first extension region EA1 may correspond to a j-th extension region overlapped a j-th sensing line, and the second extension region EA2 may correspond to a (j+1)-th extension region overlapped with a (j+1)-th sensing line.

According to some embodiments, as the shielding layer SDL covers the sensing lines TL, when viewed from the bottom of the circuit board PCB, the sensing lines TL may not include any portion directly facing the signal lines SGL without interposing a separate shielding layer SDL between the sensing lines and the signal lines SGL. Accordingly, the influence of the high frequency signal transmitted through the signal lines SGL may be reduced. In other words, noise generated in the sensing lines TL may also be reduced by reducing the coupling phenomenon between the sensing lines TL and the signal lines SGL.

In addition, according to some embodiments, the area of a region, in which the signal lines SGL and the shielding layer SDL face each other, may be reduced by forming the openings OP in the shielding layer SDL. Accordingly, the signal lines SGL may have a characteristic impedance value close to a target value by reducing the phenomenon that the characteristic impedance value of the signal lines SGL is decreased, as compared to the target value. In this case, as the openings OP of the shielding layer SDL are formed to be non-overlapped with the sensing lines TL, the signal lines SGL may have an appropriate characteristic impedance value and reduce noise generated in the sensing lines TL. Accordingly, the quality of high-frequency driving signals transmitted through the signal lines SGLs may be improved, while the accuracy and reliability in input sensing may be improved. The details thereof will be described later with Table 1.

FIGS. 6A, 6D, and 6E illustrate that the sensing lines TL have the same width and are arranged at uniform distances, and thus the openings OP also have an equal width and are arranged at uniform distances. However, the present disclosure is not limited thereto, and the sensing lines TL may be designed to have different widths depending on the position, and the openings OP may also be arranged at mutually different distances depending on the width of the sensing lines adjacent to each other. Alternatively, the sensing lines TL may be arranged at different distances depending on the positions, and the openings OP may also have different widths depending on the spacing of the sensing lines adjacent to each other.

According to some embodiments, each of the dummy extension regions EA-D may be in a non-overlap state with the sensing lines TL, when viewed in a plan view. In other words, the sensing lines TL may not be located between adjacent dummy openings OP-D or between adjacent dummy openings OP-D and openings OP, when viewed in a plan view.

Each of the dummy openings OP-D may cross at least some of the signal lines SGL passing through the overlap region OVA, when viewed in a plan view. FIG. 6A illustrates that the dummy openings OP-D cross all the signal lines SGL passing through the overlap region OVA, when viewed in a plan view. However, the present disclosure is not limited to this, and each of the dummy openings OP-D may extend to cross only some of the signal lines SGL passing through the overlap region OVA.

According to some embodiments, the area of the region, which faces the shielding layer SDL, of the signal lines SGL may be controlled through the length and/or width of each of the dummy openings OP-D so that the signal lines SGL may have an appropriate characteristic impedance value.

Meanwhile, according to some embodiments of the present disclosure, some sensing lines may be formed to be overlapped with adjacent openings as a process error occurs in the process of forming the sensing lines TL and/or forming openings in the shielding layer SDL.

As illustrated in FIG. 6B, a power line PWL may be located on the circuit board PCB according to some embodiments. According to some embodiments, the power line PWL may be located under the signal lines SGL in the overlap region OVA. The power line PWL may be located on the base layer BL to be covered by the lower insulating layer IL_B. The power line PWL of FIG. 6B may correspond to any one of the power lines PL illustrated in FIG. 4, but the present disclosure is not limited thereto. For example, the power line PWL may correspond to any one of various lines for providing a voltage to the display module DM (see FIG. 2).

Hereinafter, various embodiments of the circuit board PCB will be described. In addition, the description of circuit boards according to various embodiments will be described while focusing in mutually different components of the circuit board PCB, and the same components will be assigned with the reference numerals.

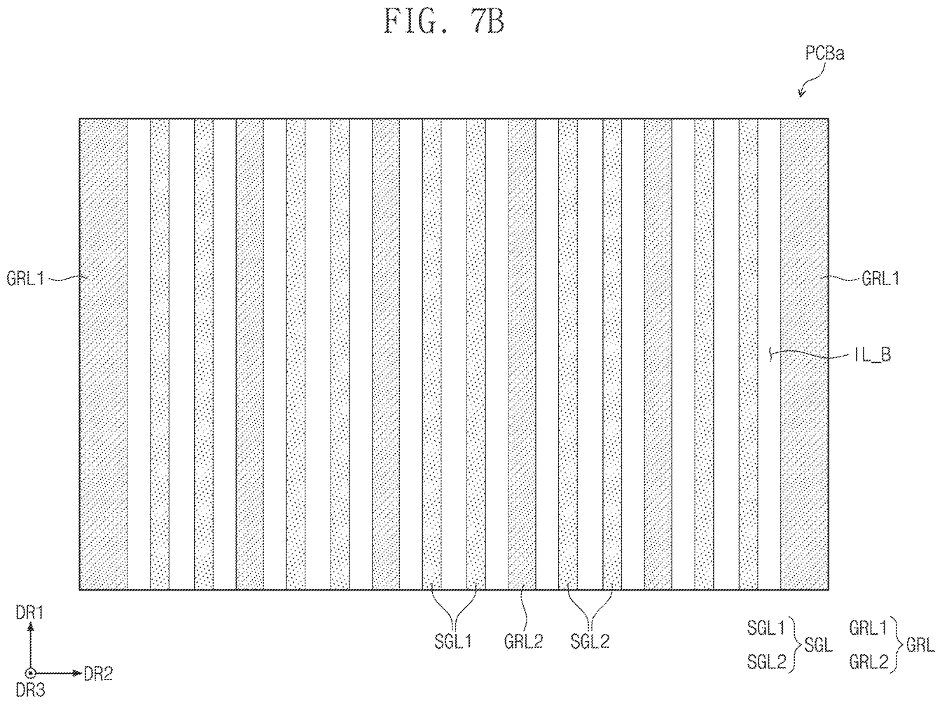

FIGS. 7A and 7B are enlarged plan views of some components of a circuit board PCBa according to some embodiments of the present disclosure. FIG. 7A illustrates a plan view corresponding to FIG. 6A.

Referring to FIGS. 7A and 7B, the signal lines SGL, the sensing lines TL, the shielding layer SDL, and grounding lines GRL may be located in the overlap region OVA of the circuit board PCBa according to some embodiments. In contrast to the circuit board PCB illustrated in FIG. 6A, the grounding lines GRL passing through the overlap region OVA may be further located in the circuit board PCBa illustrated in FIG. 7A.

FIG. 7B illustrates a plane of the signal lines SGL and the grounding lines GRL located on a lower insulating layer IL_B. According to some embodiments, the grounding lines GRL may be located at the same layer as the signal lines SGL. The grounding lines GRL may include two first sub-grounding lines GRL1 located at opposite sides of the signal lines SGL, which are located in the overlap region OVA, and spaced apart from each other in the second direction DR2 and second sub-grounding lines GRL2, each of which is located between different pairs of signal lines SGL.

According to some embodiments, planar shapes of the sensing lines TL and the shielding layer SDL located in the overlap region OVA may correspond to FIGS. 6D and 6E, and thus a detailed description thereof will be omitted.

According to some embodiments, the sensing lines TL located in the overlap region OVA may cross the second sub-grounding lines GRL2 when viewed in a plan view. In other words, each of the sensing lines TL located in the overlap region OVA may cross the second sub-grounding lines GRL2 in a region overlapped the corresponding extension region EA, when viewed in a plan view.

When viewed in a plan view, the first and second openings OP1 and OP2 may cross all of the second sub-grounding lines GRL2 located in the overlap region OVA. Accordingly, each of the second sub-grounding lines GRL2 is partially exposed from the shielding layer SDL by the first opening OP1, and another portion may be exposed from the shielding layer SDL by the second opening OP2.

The first sub-grounding lines GRL1 may be overlapped with the peripheral region SA of the shielding layer SDL when viewed in a plan view. In other words, the first sub-grounding lines GRL1 may not be exposed from the shielding layer SDL as the first sub-grounding lines GRL1 is in a non-overlap state with the openings OP of the shielding layer SDL, when viewed in a plan view.

According to some embodiments, noise generation due to coupling phenomenon between the signal lines SGL may be reduced by disposing the grounding lines GRL2 between adjacent signal lines SGL. In addition, noise generation caused by coupling between the signal lines SGL and other adjacent wires may be reduced by disposing the grounding lines GRL1 on both sides of the signal lines SGL.

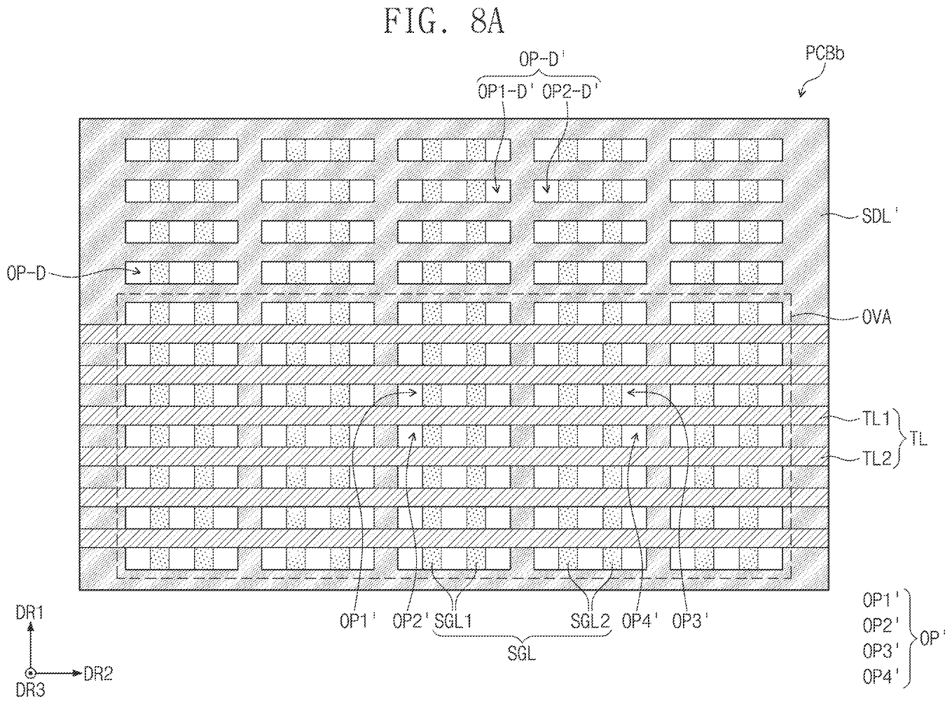

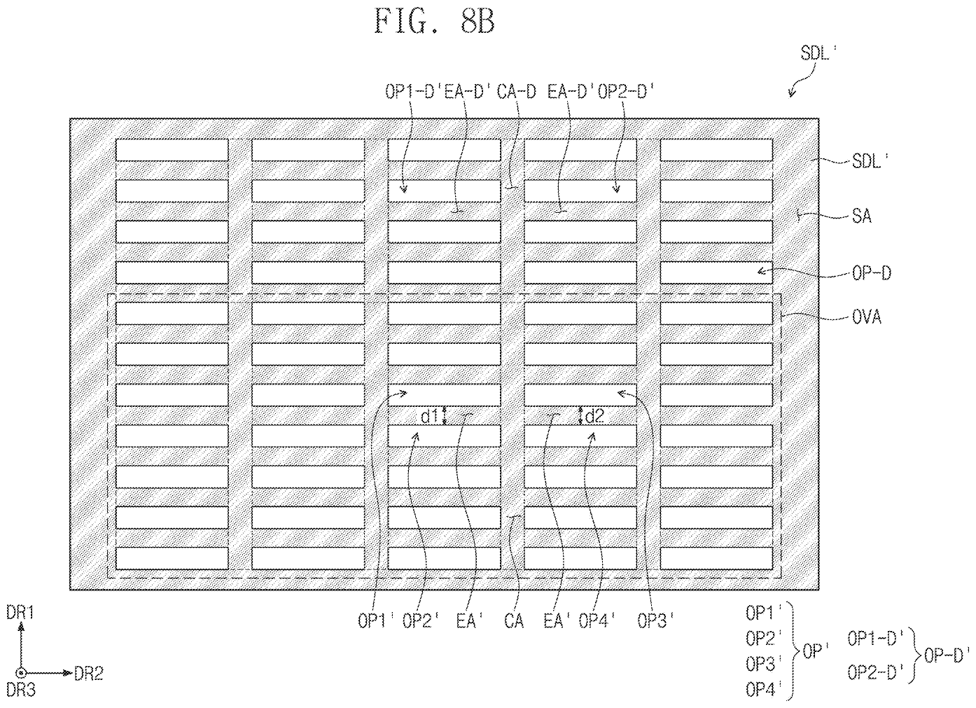

FIGS. 8A and 8B are enlarged plan views of some components of a circuit board PCBb according to some embodiments of the present disclosure. FIG. 8A illustrates a plan view corresponding to FIG. 6A. FIG. 8A illustrates the signal lines SGL, the sensing lines TL, and a shielding layer SDL′ located in the overlap region OVA, and FIG. 8B illustrates the shielding layer SDL′ of FIG. 8A. According to some embodiments, planar shapes of the signal lines SGL and the sensing lines TL located in the overlap region OVA may correspond to FIGS. 6C and 6D, respectively, and thus a detailed description thereof will be omitted.

Referring to FIGS. 8A and 8B, openings OP′ having a specific pattern may be defined in the shielding layer SDL′. According to some embodiments, in the overlap region OVA, the openings OP′ defined in the shielding layer SDL′ may extend in the second extension direction, and may be arranged in a direction perpendicular to the second extension direction and the second extension direction, respectively. According to some embodiments, the second extension direction may be a direction parallel to the second direction DR2. In other words, each of the openings OP′ may extend in the second direction DR2 and may be arranged in the first direction DR1 and the second direction DR2, respectively. The following description will be made in that the second extension direction is a direction parallel to the second direction DR2.

According to some embodiments, two openings, which are located adjacent to each other in the first direction DR1, of the openings OP′ may be defined as a first opening OP1′ and a second opening OP2′, respectively. Openings, which are adjacent to each other in the second direction DR2 from the first opening OP1′ and the second opening OP2′, of the openings OP′ may be defined as a third opening OP3′ and a fourth opening OP4′, respectively. For example, the first opening OP1′ may correspond to an opening placed in a k-th row and an I-th column of the openings OP′, and the second opening OP2′ may correspond to an opening placed in a (k+1)-th row and the l-th column of the openings OP′. The third opening OP3′ may correspond to an opening located in the k-th row and an (l+1)-th column of the openings OP′, and the fourth opening OP4′ may correspond to an opening located in the (k+1)-th row and the (l+1)-th column of the openings OP′. In this case, ‘k’ and ‘l’ are natural numbers.

According to some embodiments, each of the distance ‘d1’ between the first and second openings OP1′ and OP2′ and the distance ‘d2’ between the third and fourth openings OP3′ and OP4′ may be greater than or substantially equal to a width ‘Wt’ (see FIG. 6D) of the corresponding sensing line TL in the first direction DR1.

As the openings OP′ with a specific pattern are defined in the shielding layer SDL′, the shielding layer SDL′ may include extension regions EA′ spaced apart from each other, cross regions CA, each of which is interposed between the extension regions EA′ while crossing the extension regions EA′, and surrounding areas SA surrounding the extension regions EA′ and the cross regions CA.

According to some embodiments, the extension region EA′ may be defined as a region between adjacent openings OP′ in the first direction DR1. In other words, the extension region EA′ may be defined as a region between the first and second openings OP1′ and OP2′ (or between the third and fourth openings OP3′ and OP4′). Each of the extension regions EA′ may extend in the second direction DR2 and may be arranged in the first direction DR1 and the second direction DR2, respectively.

The cross region CA extends in the first direction DR1 and may be located between the openings OP′ located in the I-th column and the openings OP′ located in the (l+1)-th column. In other words, the cross region CA may be located between the first and third openings OP1′ and OP3′ and between the second and fourth openings OP2′ and OP4′. Each of the cross regions CA may extend in the first direction DR1 and may be arranged in the second direction DR2.

According to some embodiments, the first signal lines SGL1 may cross the first and second openings OP1′ and OP2′, respectively, when viewed in a plan view, and the second signal lines SGL2 may cross the third and fourth openings OP3′ and OP4′, respectively, when viewed in a plan view. Accordingly, each of the first signal lines SGL1 when viewed in a plan view may be partially exposed from the shielding layer SDL′ by the first opening OP1′ and a portion of each of the first signal lines SGL1 may be partially exposed from the shielding layer SDL′ by the second opening OP2′, and another portion of the first signal line SGL1 may be exposed from the shielding layer SDL′ by the second opening OP2′. Each of second signal lines SGL2 may be partially exposed from the shielding layer SDL′ by the third opening OP3′, and each of the second signal lines SGL2 may be partially exposed from the shielding layer SDL′ by the fourth opening OP4′, and another portion of the second signal line SGL2 may be exposed by the fourth opening OP4′.

The first signal lines SGL1 may cross a corresponding sensing line TL between the first and second openings OP1′ and OP2′ when viewed in a plan view, and the second signal lines SGL2 may cross a corresponding sensing line TL between the third and fourth openings OP3′ and OP4′ when viewed in a plan view.

FIG. 8A illustrates that one opening OP′ or one extension region EA′ crosses two signal lines SGL when viewed in a plan view, and one opening OP′ or one extension region EA′ may extend while crossing various number of signal lines SGL.

According to some embodiments of the present disclosure, dummy openings OP-D′ with a specific pattern may be further defined on the shielding layer SDL′ outside the overlap region OVA. According to some embodiments, the dummy openings OP-D′ may be defined to have a pattern similar to that of the openings OP′. More specifically, the dummy openings OP-D′ may be spaced apart from the openings OP′ in the first direction DR1, and each of the dummy openings OP-D′ may extend in the second direction DR2 and may be arranged in the first direction DR1 and the second direction DR2.

According to some embodiments, two dummy openings located adjacent to each other in the second direction DR2 of the dummy openings OP-D′ may be defined as a first dummy opening OP1-D′ and a second dummy opening OP2-D′, respectively.

For example, the first dummy opening OP1-D′ may correspond to the dummy opening placed in the m-th row and the n-th column, and the second dummy opening OP2-D′ may correspond to the dummy opening placed in the m-th row and the (n+1)-th column. In this case, ‘m’ and ‘n’ are natural numbers.

When the dummy openings OP-D′ having a specific pattern are further defined in the shielding layer SDL′, the shielding layer SDL′ may further include dummy extension regions EA-D′ arranged to be spaced apart from each other and dummy cross regions CA-D extending from cross regions CA and crossing the dummy extension regions EA-D′ between the dummy extension regions EA-D′. The dummy extension regions EA-D′ and the dummy cross regions CA-D may be surrounded by the peripheral region SA.

According to some embodiments, each of the dummy extension regions EA-D′ may be in a non-overlap state with the sensing lines TL when viewed in a plan view. In other words, the sensing lines TL may be misplaced between adjacent dummy openings OP-D′ or between adjacent dummy openings OP-D′ and openings OP′, when viewed in a plan view.

Each of the first signal lines SGL1 may cross the first dummy opening OP1-D′ when viewed in a plan view, and each of the second signal lines SGL2 may cross the second dummy opening OP2-D′ when viewed in a plan view. Accordingly, each of the first signal lines SGL1 may be partially exposed from the shielding layer SDL′ by the first dummy opening OP1-D′, and each of the second signal lines SGL2 may be partially exposed from the shielding layer SDL′ by the second dummy opening OP2-D′.

FIG. 8A illustrates that the dummy opening OP-D′ or the dummy extension region EA-D′ crosses two signal lines SGL when viewed in a plan view, and the dummy opening OP-D′ or the dummy extension region EA-D′ may be extended to cross various number of signal lines SGL.

Meanwhile, according to some embodiments of the present disclosure, the circuit board PCBb may further include grounding lines GRL described above with reference to FIG. 7B. Referring to FIGS. 7B, 8A, and 8B together, the grounding lines GRL may include the first sub-grounding lines GRL1 and the second sub-grounding lines GRL2.

According to some embodiments, the second sub-grounding lines GRL2 may be arranged to be overlapped with the cross regions CA, respectively. The second sub-grounding lines GRL2 may be interposed between the first and third openings OP1′ and OP3′ and between the second and fourth openings OP2′ and OP4′. Accordingly, the second sub-grounding lines GRL2 may be covered by the shielding layer SDL′ when viewed in a plan view.

However, embodiments according to the present disclosure are not limited thereto, and the second sub-grounding lines GRL2 may be arranged to cross the openings OP′ to be exposed from the shielding layer SDL′ by the opening OP′ when viewed in a plan view, and only some of the second sub-grounding lines GRL2 may be arranged to be overlapped with the cross regions CA and the remaining grounding lines of the second sub-grounding lines GRL2 may be arranged to cross the openings OP′.

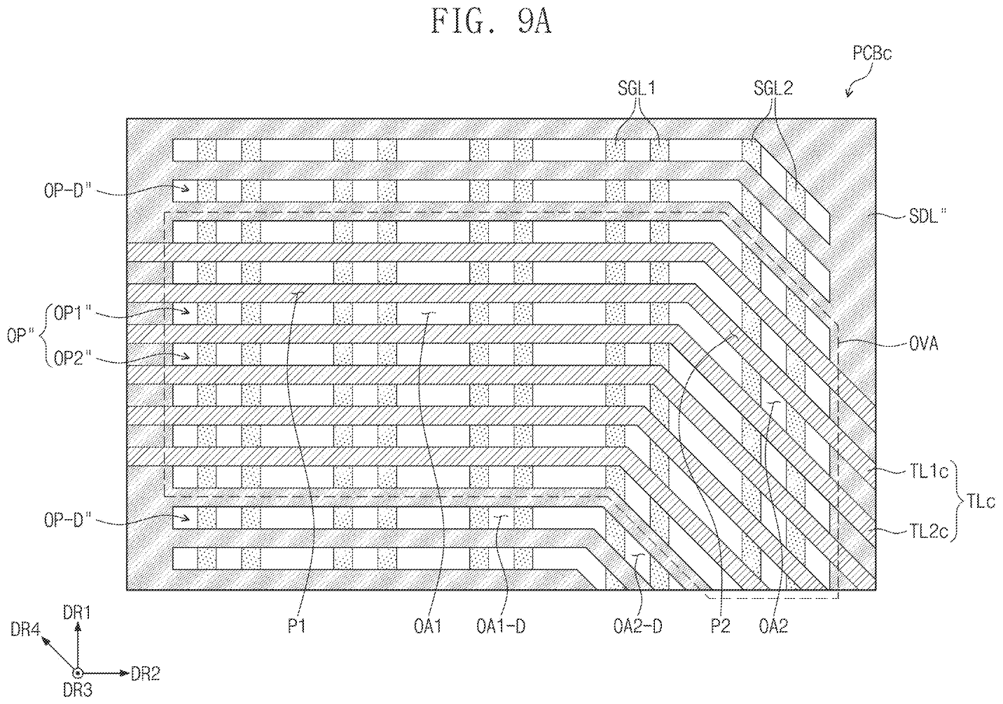

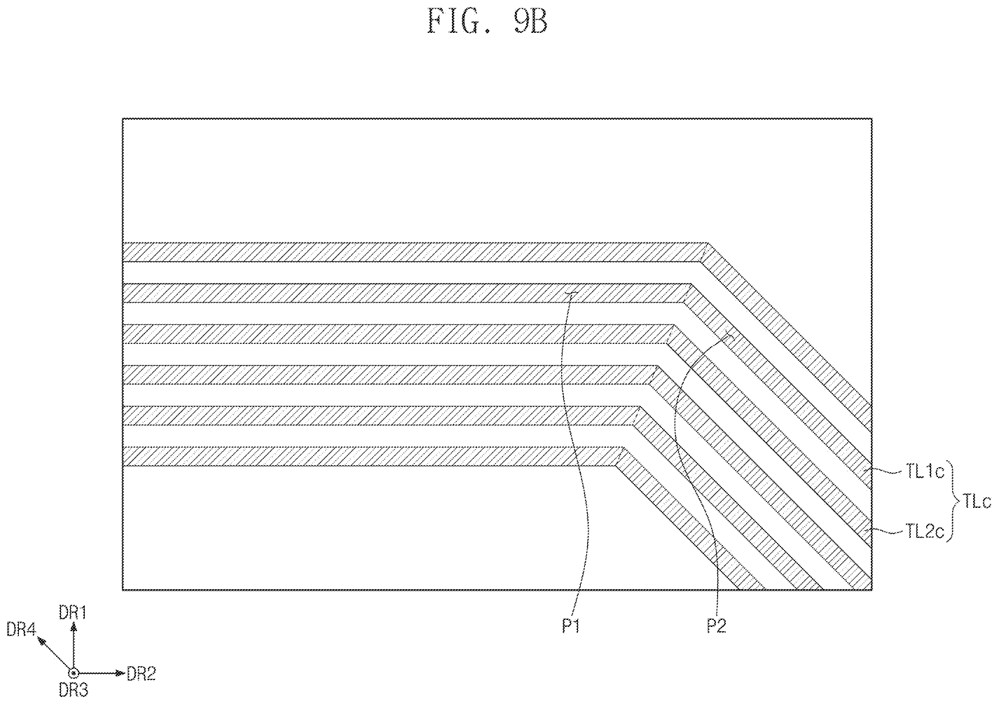

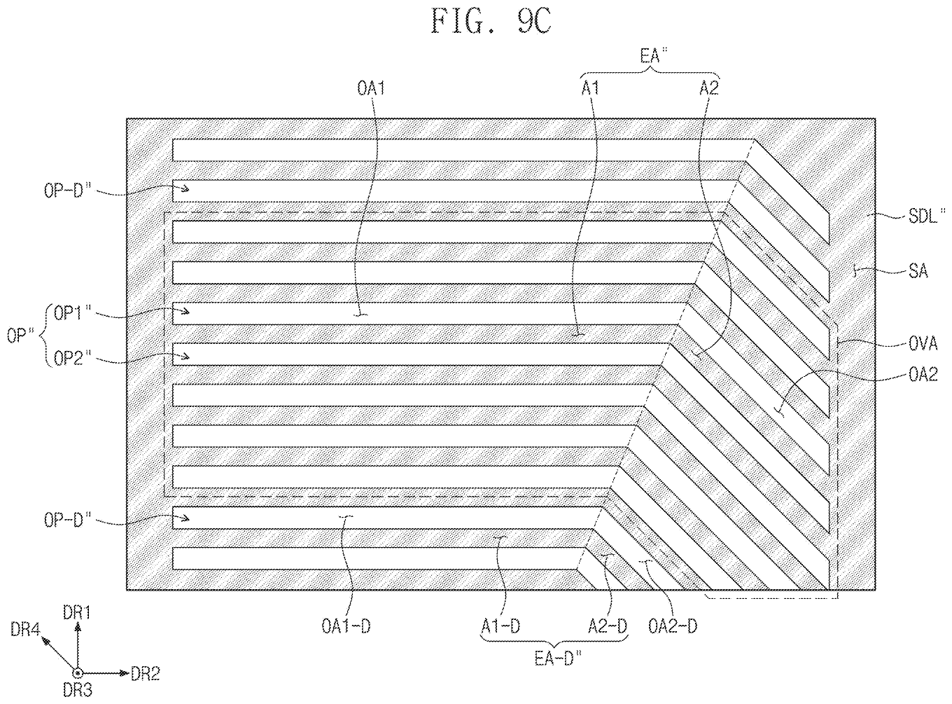

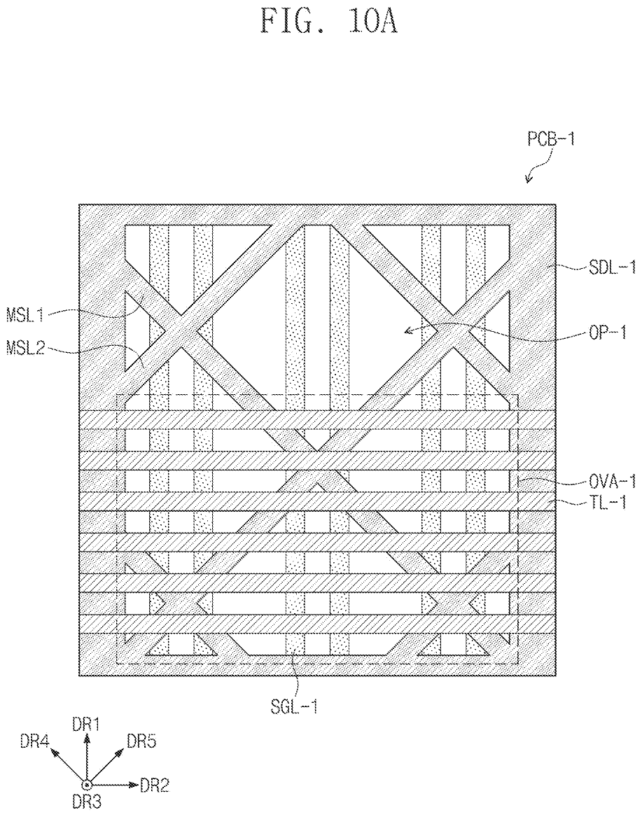

FIGS. 9A to 9C are enlarged plan views of some components of a circuit board PCBc according to some embodiments of the present disclosure. FIG. 9A illustrates a plan view corresponding to FIG. 6A. FIG. 9A illustrates the signal lines SGL, sensing lines TLc, and shielding layer SDL″ located in the overlap region OVA. The sensing lines TLc of FIG. 9A are illustrated in FIG. 9B, and the shielding layer SDL″ of FIG. 9A is illustrated in FIG. 9C. According to some embodiments, since the planar shape of the signal lines SGL located in the overlap region OVA may correspond to FIG. 6C, the details thereof will be omitted.

Referring to FIGS. 9A to 9C together, each of the sensing lines TLc located in the overlap region OVA may include a first part P1 extending in the second extension direction and a second part P2 extending in a third extension direction from the first part P1. The third extension direction may be a direction crossing the first and second extension directions. According to some embodiments, the second extension direction may be a direction parallel to the second direction DR2, and the third extension direction may be a direction parallel to a fourth direction DR4 defined as a direction crossing the first and second directions DR1 and DR2. In other words, according to some embodiments, each of the sensing lines TLc may include a portion bent in the overlap region OVA. The following description will be made in that the second extension direction is a direction parallel to the second direction DR2, and the third extension direction is a direction parallel to the fourth direction DR4.

Each of the openings OP″ may include a first opening region OA1 extending in the second direction DR2 and a second opening region OA2 extending in the fourth direction DR4 from the first opening region OA1. The first opening region OA1 of each of first and second openings OP1″ and OP2″ may extend in parallel along a first portion P1 of the corresponding sensing line TLc, and the second opening region OA2 of each of the first and second openings OP1″ and OP2″ may extend along a second portion P2 of the corresponding sensing line TLc.

Accordingly, each of the extension regions EA″ of the shielding layer SDL″ may include a first area A1 extending in the second direction DR2 and a second area A2 extending in the fourth direction DR4 from the first area A1. The first area A1 may be overlapped with the first portion P1 of the corresponding sensing line TLc, and the second area A2 may be overlapped with the second portion P2 of the corresponding sensing line TLc.

According to some embodiments, each of the sensing lines TLc may cross a part of the signal lines SGL in the first part P1 and may cross the remaining part of the signal lines SGL in the second part P2, when viewed in a plan view. For example, the first portion P1 of the sensing line TLc may cross each of the first signal lines SGL1, and the second portion P2 of the sensing line TLc may cross each of the second signal lines SGL2. In addition, the first signal lines SGL1 are partially exposed from the shielding layer SDL″ by the first opening region OA1 of each of the first and second openings OP1″ and OP2″, and the second signal lines SGL2 may be partially exposed from the shielding layer SDL″ by the second opening region OA2 of each of the first and second openings OP1″ and OP2″.

According to some embodiments of the present disclosure, the dummy openings OP-D″ may be further defined in the shielding layer SDL″, and the dummy openings OP-D″ may be defined to have a pattern similar to those of the openings OP″ outside the overlap region OVA. Each of the dummy openings OP-D″ may include a first dummy opening region OA1-D extending in the second direction DR2 and a second dummy opening region OA2-D extending in the fourth direction DR4 from the first dummy opening region OA1-D.

When the dummy openings OP-D″ are further defined in the shielding layer SDL″, the shielding layer SDL″ may further include dummy extension regions EA-D″ spaced apart from each other and surrounded by the peripheral region SA. Each of the dummy extension regions EA-D″ may include a first dummy region A1-D extending in the second direction DR2 and a second dummy region A2-D extending in the fourth direction DR4 from the first dummy region A1-D.

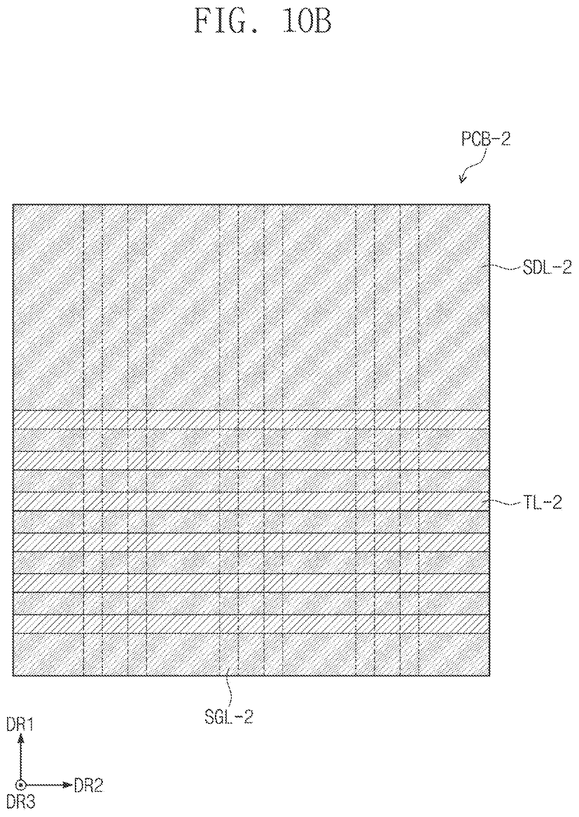

FIG. 10A is an enlarged plan view of some components of a circuit board PCB-1 according to a first comparative example. In FIG. 10A, signal lines SGL-1, sensing lines TL-1, and shielding layer SDL-1 are illustrated in an overlap region OVA-1. FIG. 10A illustrates six signal lines SGL-1 and six sensing lines TL-1 crossing each other when viewed in a plan view.

Referring to FIG. 10A, openings OP-1 may be defined in the shielding layer SDL-1 to have a mesh-shaped pattern. The shielding layer SDL-1 may include first mesh lines MSL1 extending in the fourth direction DR4 and second mesh lines MSL2 extending in a fifth direction DR5, and the mesh-shaped pattern may be formed by the first and second mesh lines MSL1 and MSL2. The fourth direction DR4 is defined as a direction crossing the first and second directions DR1 and DR2, and the fifth direction DR5 is defined as a direction perpendicular to the fourth direction DR4. The openings OP-1 may be defined by the first and second mesh lines MSL1 and MSL2.

The signal lines SGL-1 may extend in the first direction DR1. The signal lines SGL-1 may cross the mesh lines MSL1 and MSL2 when viewed in a plan view.

The sensing lines TL-1 may extend in the second direction DR2. The sensing lines TL-1 may cross the mesh lines MSL1 and MSL2 when viewed in a plan view.

FIG. 10B is an enlarged plan view of some components of a circuit board PCB-2 according to a second comparative example. In FIG. 10B, signal lines SGL-2, sensing lines TL-2, and shielding layer SDL-2 are illustrated in an overlap region OVA-2. FIG. 10B illustrates six signal lines SGL-2 and six sensing lines TL-2 crossing each other when viewed in a plan view.

Referring to FIG. 10B, the shielding layer SDL-2 may be implemented as a through electrode without defining openings in the overlap region OVA-2 and having no 1 separate pattern. In other words, in the overlap region OVA-2, all the signal lines SGL-2 and the sensing lines TL-2 may be overlapped with the shielding layer SDL-2, and the signal lines SGL-2 may be covered by the shielding layer SDL-2 when viewed in a plan view. In FIG. 10B, the signal lines SGL-2 are illustrated as dotted lines.

Table 1 shows, in the case of the first Comparative Example, the second Comparative Example, and the present embodiments, the coupling voltage mV generated from the sensing lines and the characteristic impedance (0) of the signal lines were measured and illustrated. The shielding layers having different shapes were applied in each of the first comparative example, the second comparative example, and the present embodiments. In the first comparative example, the shielding layer SDL-1 has a mesh-shaped pattern in a region in which the signal lines SGL-1 and the sensing lines TL-1 are overlapped with each other, as illustrated in FIG. 10A. In the second comparative example, the shielding layer SDL-2 is provided as a through electrode in a region in which the signal lines SGL-2 and the sensing lines TL-2 are overlapped with each other as illustrated in FIG. 10B. According to some embodiments, the shielding layer SDL includes the extension regions EA extending side by side along the sensing lines TL, including the openings OP located between the sensing lines TL in a region in which the signal lines SGL and the sensing lines TL are overlapped with each other as illustrated in FIG. 6A. Hereinafter, the measurement result values of Table 1 will be described with reference to FIGS. 6A, 10A, and 10B.

TABLE 1

| | Coupling | Characteristic |
|---|---|---|
| | voltage [mV] | impedance [Ω] |
| First comparative example | 21 | 95 |
| Second comparative example | 0.5 | 75 |
| Present embodiment | 2.2 | 86 |

The coupling voltage (mV) generated in the sensing lines results from a coupling phenomenon caused as the sensing lines cross with the signal lines transmitting high-frequency signals, and the first comparative example, the second comparative Example, and the present embodiments were compared to each other in terms of noise caused in the sensing lines.

Referring to the results of Table 1, the coupling voltage is increased in the order of the second comparative example, the present embodiments, and the first comparative example.

In the second comparative example, since the shielding layer SDL-2 is provided to be overlapped with the sensing lines TL-2 and the signal lines SGL-2 within the overlap region OVA-2, the coupling voltage generated in the sensing lines TL-2 due to the high-frequency signal transmitted to the signal lines SGL-2 may be low. In other words, in the second comparative example, a smaller amount of noise may be generated in driving signals transmitted or received by the sensing lines TL-2.

Meanwhile, in the first comparative example, as the openings OP-1 of the shielding layer SDL-1 the overlap region OVA-1 are overlapped with some of the signal lines SGL-1 and some of the sensing lines TL-1, the high-frequency signals transmitted to the signal lines SGL-1 may generate a high coupling voltage in the sensing lines TL-1 through the openings OP-1. In other words, in the first comparative example, a larger amount of noise may be generated in driving signals transmitted or received through the sensing lines TL-1.

According to some embodiments, the shielding layer SDL may be arranged to be overlapped with the sensing lines TL within the overlap region OVA, and may expose some of the signal lines SGL through the openings OP. Accordingly, according to some embodiments, the coupling voltage generated in the sensing lines TL due to the high frequency signal transmitted through the signal lines SGL may be higher than that of the second comparative example and lower than that of the first comparative example. According to some embodiments, a coupling voltage, which is reduced by about 90% compared to the first comparative example, may be generated in the sensing lines TL. In other words, according to some embodiments, it may be confirmed that the sensing lines TL generate more noise than the second comparative example but less noise than the first comparative example.

When the coupling voltage generated in the sensing lines is 12 mV or less, the error rate in input sensing for the final product may have a small level, thereby maintaining a high level of accuracy and reliability. According to some embodiments, it may be recognized that the coupling voltage generated in the sensing lines TL satisfies the condition of 12 mV or less, thereby showing the higher accuracy and reliability in input sensing.

In the circuit board used for this measurement, the target value of the characteristic impedance of the signal lines is 100 (0). The characteristic impedance was measured with respect to the signal lines according to the first comparative example, the second comparative example, and the present embodiments, and the first comparative example, the second comparative example, and the present embodiments were measured in terms of a degree close to suitable characteristic impedance, that is. the reduction degree from the target value.

The impedance of the signal lines becomes a function of resistance, conductance, capacitance, and inductance as illustrated in Equation 1 below.

$${Z}_{o} = \sqrt{\frac{R + j ω L}{G + j ω C}} \qquad Equation 1$$

In this case, Zo is the characteristic impedance of the signal lines, R is the resistance, G is the conductance, w is the radian frequency (i.e., 2πf), j is \sqrt{−1}, L is the inductance, and C is the capacitance of the signal lines.

In a high frequency, a characteristic impedance is preferentially determined by a capacitance and an inductance, and Equation 1 is abbreviated to following Equation 2.

$${Z}_{o} = \sqrt{\frac{L}{C}} \qquad Equation 2$$

In Equation 2, as the inductance is proportional to the strength of a magnetic field, and the capacitance is proportional to the strength of an electric field, the characteristic impedance may be proportional to

$$\sqrt{\frac{H}{E}} .$$

In this case, ‘H’ denotes the strength of the magnetic field, and ‘E’ denotes the strength of the electric field. Accordingly, the characteristic impedance is inversely proportional to the strength of the electric field.

Referring to the results of Table 1, according to the first Comparative Example, the signal lines SGL-1 have characteristic impedance reduced by 5% from the characteristic impedance of the target value. According to the second comparative example, the signal lines SGL-2 have characteristic impedance reduced by 25% from the characteristic impedance of the target value. According to some embodiments, the signal lines SGL have characteristic impedance in reduced by 14% from the characteristic impedance of the target value. The reduction degree of the characteristic impedance is increased in the order of the first comparative example, the present embodiments, and the second comparative example.

In the first comparative example, the strength of the electric field formed between the signal lines SGL-1 and the shielding layer SDL-1 may be lower, as a relatively large portion of the signal lines SGL-1 is overlapped the openings OP-1 of the shielding layer SDL-1. Accordingly, it may be recognized that the signal lines SGL-1 according to the first comparative example have characteristic impedance in which the reduction degree from the target value is smaller.

Meanwhile, in the second comparative example, as the signal lines SGL-2 are overlapped with the shielding layer SDL-2 in all regions, the strength of the electric field formed between the signal lines SGL-2 and the shielding layer SDL-2 may be large. Accordingly, it may be recognized that the signal lines SGL-2 according to the second comparative example have characteristic impedance in which the reduction degree from the target value is greater.

According to some embodiments, there may be few parts where the signal lines SGL are overlapped with the openings OP of the shielding layer SDL, as compared to the case where the shielding layer SDL-1 has a mesh-shaped pattern. Accordingly, the strength of the electric field formed between the signal lines SGL and the shielding layer SDL may be higher than the first comparative example but lower than the second comparative example. Accordingly, it may be recognized that the signal lines SGL according to the present embodiments have the reduction degree from the target value, which is greater than that of the first comparative example, but lower than that of the second comparative example.

When the reduction degree from the target value of the characteristic impedance of the signal lines is equal to or less than 15%, the degree, in which the driving signal of the high frequency transmitted though the signal lines is modified, in the final product is slight. Accordingly, the higher quality may be maintained. According to some embodiments, the reduction rate of the characteristic impedance of the signal lines SGL meets the condition of 15% or less. Accordingly, it may be recognized that the high-frequency driving signal transmitted through the signal lines SGL may have higher quality according to some embodiments.

Accordingly, as shown in Table 1, as the signal lines SGL-1 according to the first comparative example has the characteristic impedance closer to the target value, the excellent quality is shown in the driving signals received through the signal lines SGL-1. However, as noise is largely generated in the sensing lines TL-1, the accuracy in input sensing may be degraded. To the contrary, in the second comparative example, the accuracy in input sensing may be increased as noise is less generated in the sensing lines TL-2. However, as the signal lines SGL-2 shows characteristic impedance having a big difference from the target value, the quality of the driving signals received through the signal lines SGL-2 may be degraded.

To the contrary, according to some embodiments, it may be recognized that the signal lines SGL have characteristic impedance within an appropriate range, and the coupling voltage generated in the sensing lines TL also falls within a range which does not affect the accuracy in input sensing. Accordingly, according to some embodiments, it may be recognized that the quality of driving signals received through the sensing lines TL may be improved while also improving the accuracy in input sensing.

As described above, according to some embodiments, the shielding layer may be formed between the signal lines and the sensing lines, and openings having a specific pattern may be provided in the shielding layer, such that the signal lines have an impedance having an appropriate characteristic. In addition, as the coupling degree may be reduced between the signal lines and the sensing lines adjacent to each other, noise generated in the sensing lines is reduced. Accordingly, the quality of the high-frequency driving signals transmitted through the signal lines may be relatively improved and the accuracy and the reliability in input sensing may be relatively improved.

Although aspects of some embodiments of the present disclosure have been described for illustrative purposes, those skilled in the art will appreciate that various modifications, and substitutions are possible, without departing from the scope and spirit of the invention as disclosed in the accompanying claims. Accordingly, the technical scope of the present disclosure is not limited to the detailed description of this specification, but should be defined by the claims, and their equivalents.

While aspects of some embodiments of the present disclosure have been described with reference to embodiments thereof, it will be apparent to those of ordinary skill in the art that various changes and modifications may be made thereto without departing from the spirit and scope of the present disclosure as set forth in the following claims, and their equivalents.

What is claimed is:

1. A display device comprising:
a display module including a display panel and an input sensing unit; and
a circuit board connected to the display module,
wherein the circuit board includes:
a first signal line electrically connected to the display panel and having at least a portion extending in a first extension direction;
a sensing line electrically connected to the input sensing unit and having at least a portion extending in a second extension direction crossing the first extension direction; and
a shielding layer interposed between the first signal line and the sensing line and having a first opening and a second opening spaced apart from each other while interposing the sensing line in a plan view,
wherein at least a portion of each of the first opening and the second opening extends in the second extension direction,
wherein the sensing line crosses the first signal line between the first opening and the second opening in the plan view, and
wherein a distance between the first opening and the second opening is greater than or equal to a width of the sensing line in the plan view.

2. The display device of claim 1, wherein a portion of the first signal line is exposed from the shielding layer through each of the first opening and the second opening in the plan view.

3. The display device of claim 1, wherein the circuit board further includes:
a second signal line electrically connected to the display panel, spaced apart from the first signal line, and extending in parallel to the first signal line, and
wherein the second signal line crosses the sensing line, between the first opening and the second opening in the plan view.

4. The display device of claim 3, wherein the circuit board further includes:
a grounding line interposed between the first signal line and the second signal line and extending in parallel to the first signal line, and
wherein a portion of the grounding line is exposed from the shielding layer through each of the first opening and the second opening in the plan view.

5. The display device of claim 1, wherein the circuit board further includes:
a second signal line electrically connected to the display panel, spaced apart from the first signal line, and extending in parallel to the first signal line,
wherein the shielding layer has a third opening and a fourth opening additionally defined in the shielding layer, arranged in the second extension direction from the first opening and the second opening, respectively, and spaced apart from each other while interposing the sensing line between the third opening and the fourth opening,
wherein the second signal line crosses the sensing line between the third opening and the fourth opening in the plan view, and
wherein a distance between the third opening and the fourth opening is greater than or equal to the width of the sensing line in the plan view.

6. The display device of claim 5, wherein the circuit board further includes:
a grounding line interposed between the first signal line and the second signal line and extending in parallel to the first signal line, and
wherein the grounding line is interposed between the first opening and the third opening, and between the second opening and the fourth opening in the plan view.

7. The display device of claim 1, wherein the sensing line includes:
a first part extending in the second extension direction and a second part extending in a third extension direction crossing each of the first extension direction and the second extension direction, and
wherein each of the first opening and the second opening includes:
a first opening region extending in the second extension direction and a second opening region extending in the third extension direction from the first opening region.

8. The display device of claim 7, wherein the first part is interposed between the first opening region of the first opening and the first opening region of the second opening, and
wherein the second part is interposed between the second opening region of the first opening and the second opening region of the second opening.

9. The display device of claim 1, wherein the first signal line is configured to transmit a high-frequency signal.

10. The display device of claim 1, wherein the shielding layer is configured to receive a grounding voltage.

11. The display device of claim 1, wherein the circuit board further includes:
a base layer under the first signal line;
a first insulating layer interposed between the first signal line and the shielding layer; and
a second insulating layer interposed between the shielding layer and the sensing line.

12. The display device of claim 11, wherein the circuit board further includes:
a lower insulating layer interposed between the base layer and the first signal line; and
a power line interposed between the base layer and the lower insulating layer.

13. A display device comprising:
a display module including a display panel and an input sensing unit; and
a circuit board connected to the display module,
wherein the circuit board further includes:
a first signal line electrically connected to the display panel;
a shielding layer on the first signal line and including a first extension region and a second extension region spaced apart from each other, and a peripheral region surrounding the first extension region and the second extension region; and
a sensing line on the shielding layer, electrically connected to the input sensing unit, and including a first sensing line having a portion overlapped with the first extension region and a second sensing line having a portion overlapped with the second extension region,
wherein the first sensing line crosses the first signal line in a region overlapped with the first extension region, and the second sensing line crosses the first signal line in a region overlapped with the second extension region in a plan view, and
wherein a width of the first extension region is greater than or equal to a width of the first sensing line, in a region in which the first extension region is overlapped with the first sensing line.

14. The display device of claim 13, wherein the shielding layer further includes:
a dummy extension region spaced apart from the first extension region, extending in parallel to the first extension region, and surrounded by the peripheral region, and
wherein the dummy extension region is in a non-overlap state with the sensing line and crosses the first signal line in the plan view.

15. The display device of claim 13, wherein the shielding layer further includes a third extension region and a fourth extension region surround by the peripheral region, another portion of the first sensing line is overlapped with the third extension region, and another portion of the second sensing line is overlapped with the fourth extension region.

16. The display device of claim 15, wherein the circuit board further includes:
a second signal line electrically connected to the display panel, spaced apart from the first signal line, and extending in parallel to the first signal line, and
wherein the first sensing line crosses the second signal line in a region overlapped with the third extension region, and the second sensing line crosses the second signal line in a region overlapped with the fourth extension region in the plan view.

17. The display device of claim 13, wherein the first signal line has at least a portion extending in a first extension direction in a region overlapped with the shielding layer,
wherein the first sensing line:
includes a first part extending in a second extension direction crossing the first extension direction and a second part extending in a third extension direction crossing each of the first extension direction and the second extension direction from the first part, and
wherein the first extension region includes:
a first region extending in the second extension direction and overlapped with the first part and a second region extending in the third extension direction from the first region and overlapped with the second part.

18. The display device of claim 17, wherein the shielding layer further includes:
a dummy extension region spaced apart from the first extension region, is in a non-overlap state with the sensing line, and is surrounded by the peripheral region, and
wherein the dummy extension region includes a first dummy region extending in the second extension direction and a second dummy region extending in the third extension direction from the first dummy region.

19. The display device of claim 13, wherein the circuit board further includes:
a grounding line spaced apart with the first signal line and extending in parallel to the first signal line.

20. A display device comprising:
a display module configured to provide an image and to sense an external input; and
a circuit board connected to the display module,
wherein the circuit board further includes:
a first line electrically connected to the display module to transmit a high-frequency signal and having at least a portion extending in a first extension direction;
a second line electrically connected to the display module, and having at least a portion extending in a second extension direction crossing the first extension direction; and
a shielding layer interposed between the first line and the second line and having a first opening and a second opening spaced apart from each other while interposing the second line, in a plan view, wherein at least a portion of each of the first opening and the second opening extends in the second extension direction,
wherein the second line crosses the first line between the first opening and the second opening in the plan view, and
wherein a distance between the first opening and the second opening is greater than or equal to a width of the second line in the plan view.
